(19) United States
(12) Patent Application Publication
(10) Pub. No.: US 2026/0334310 A1
(43) Pub. Date: Oct. 22, 2026

(54) SEMICONDUCTOR DEVICE, METHOD OF MANUFACTURING THEREOF, PACKAGE STRUCTURE AND ELECTRONIC DEVICE

(71) Applicant: Yangtze Memory Technologies Holding Co., Ltd., Wuhan (CN)

(72) Inventors: Yu Zhang, Wuhan (CN); Zongliang Huo, Wuhan (CN); Lei Jin, Wuhan (CN); Xiaoxin Liu, Wuhan (CN); Feng Xu, Wuhan (CN)

(73) Assignee: Yangtze Memory Technologies Holding Co., Ltd., Wuhan (CN)

(21) Appl. No.: 19/374,743

(22) Filed: Oct. 30, 2025

(30) Foreign Application Priority Data
Apr. 16, 2025 (CN) 202510480594.9

(51) Int. Cl. H01L 25/18; H01L 23/00; H01L 23/522; H01L 23/528; H01L 25/00; H10B 80/00; H10D 80/30

(52) U.S. Cl. CPC H10W 90/00; H10B 80/00; H10D 80/30; H10W 20/42; H10W 20/435; H10W 90/26; H10W 90/297; H10W 90/792

(57) ABSTRACT

The examples of the present disclosure disclose a semiconductor device and a method thereof, a package structure and an electronic device. The semiconductor device includes a first semiconductor structure, a second semiconductor structure and a third semiconductor structure sequentially stacked along a first direction; the first semiconductor structure includes an analog-to-digital conversion circuit and an interface circuit, the second semiconductor structure includes a memory array, the third semiconductor structure includes a peripheral circuit coupled to the memory array and the analog-to-digital conversion circuit, respectively; the analog-to-digital conversion circuit is configured to receive analog information obtained by performing an operation by the memory array; wherein the first semiconductor structure further includes a pad coupled to the interface circuit and located on one side, away from the second semiconductor structure, of two opposite sides of the analog-to-digital conversion circuit along the first direction.

### CROSS-REFERENCE TO RELATED APPLICATIONS

This application claims the benefit of priority to Chinese Application No. 202510480594.9, filed on Apr. 16, 2025, which is hereby incorporated by reference in its entirety.

### FIELD OF TECHNOLOGY

Examples of the present disclosure relate to the field of semiconductor technology, and relate to, but are not limited to, a semiconductor device, a method of manufacturing thereof, and a memory system.

### BACKGROUND

In the classical von Neumann computing architecture, the memory is separate from the processor, and the data is transmitted between the memory and the processor through the data bus. When executing the command, the processor first reads the data from the memory, and then writes the updated data back to the memory after being processed, and frequent data migration brings huge power consumption and time overhead. In addition, since the bandwidth of the memory is limited, the processing speed of the processor is limited by the access speed of the memory, which greatly affects the computing performance. With the rise of applications such as big data and artificial intelligence, massive data processing makes the bottleneck of the von Neumann computing architecture more and more prominent.

### SUMMARY

According to a first aspect of the examples of the present disclosure, a semiconductor device is provided, including: a first semiconductor structure, a second semiconductor structure and a third semiconductor structure sequentially stacked along a first direction; where the first semiconductor structure includes an analog-to-digital conversion circuit and an interface circuit, the second semiconductor structure includes a memory array, the third semiconductor structure includes a peripheral circuit coupled to the memory array and the analog-to-digital conversion circuit, respectively, and the analog-to-digital conversion circuit is configured to receive analog information obtained by performing an operation by the memory array; and where the first semiconductor structure further includes a pad coupled to the interface circuit and located on one side, away from the second semiconductor structure, of two opposite sides of the analog-to-digital conversion circuit along the first direction; or the third semiconductor structure further includes a pad coupled to the interface circuit and located on one side, away from the second semiconductor structure, of two opposite sides of the peripheral circuit along the first direction.

In some examples, the first semiconductor structure further includes a first semiconductor layer located between the pad and the second semiconductor structure, and both a portion of the analog-to-digital conversion circuit and a portion of the interface circuit are located in the first semiconductor layer.

In some examples, the first semiconductor structure further includes a first dielectric structure, a first conductive structure, and a second conductive structure; where the first dielectric structure is located between the first semiconductor layer and the second semiconductor structure, and both the first conductive structure and the second conductive structure are located in the first dielectric structure; and where the pad is coupled to the interface circuit through the first conductive structure, and the peripheral circuit is coupled to the analog-to-digital conversion circuit through the second conductive structure.

In some examples, the first semiconductor structure further includes a first connection structure extending through the first semiconductor layer along the first direction; where two opposite ends of the first connection structure along the first direction are connected to the pad and the first conductive structure, respectively.

In some examples, the first dielectric structure includes a first dielectric layer and a first interconnection dielectric layer, the first dielectric layer is located between the first semiconductor layer and the first interconnection dielectric layer, and the first interconnection dielectric layer is located between the first dielectric layer and the second semiconductor structure; where the first conductive structure includes a first contact structure and a first interconnection structure, the first contact structure extends through the first dielectric layer along the first direction, and the first interconnection structure is located in the first interconnection dielectric layer; and where two opposite ends of the first contact structure along the first direction are connected to the first connection structure and the first interconnection structure, respectively; and where the second conductive structure includes a second contact structure and a second interconnection structure, the second contact structure extends through the first dielectric layer along the first direction, and the second interconnection structure is located in the first interconnection dielectric layer; and where two opposite ends of the second contact structure along the first direction are connected to the analog-to-digital conversion circuit and the second interconnection structure, respectively.

In some examples, the first semiconductor structure further includes a first dielectric structure, a first conductive structure, and a second conductive structure; where the first dielectric structure is located between the pad and the first semiconductor layer, and both the first conductive structure and the second conductive structure are located in the first dielectric structure; and where the pad is coupled to the interface circuit through the first conductive structure, and the peripheral circuit is coupled to the analog-to-digital conversion circuit through the second conductive structure.

In some examples, the first semiconductor structure further includes a first connection structure extending through the first semiconductor layer along the first direction; where the peripheral circuit is coupled to the second conductive structure through the first connection structure.

In some examples, the first dielectric structure includes a first dielectric layer and a first interconnection dielectric layer; the first dielectric layer is located between the first semiconductor layer and the first interconnection dielectric layer, and the first interconnection dielectric layer is located between the first dielectric layer and the pad; the first conductive structure includes a first contact structure and a first interconnection structure, the first contact structure extends through the first dielectric layer along the first direction, and the first interconnection structure is located in the first interconnection dielectric layer; where the pad is connected to the first interconnection structure, and two opposite ends of the first contact structure along the first direction are connected to the first interconnection structure and the interface circuit, respectively; the second conductive structure includes a second contact structure, a third contact structure, and a conductive line; both the second contact structure and the third contact structure extend through the first dielectric layer along the first direction, and the conductive line is located in the first interconnection dielectric layer; where two opposite ends of the second contact structure along the first direction are connected to the analog-to-digital conversion circuit and the conductive line, respectively, and two opposite ends of the third contact structure along the first direction are connected to the first connection structure and the conductive line, respectively.

In some examples, the first semiconductor structure further includes a second connection structure and a controller, the second connection structure extends through the first semiconductor layer along the first direction, and a portion of the controller is located in the first semiconductor layer; where the peripheral circuit is coupled to the controller through the second connection structure.

In some examples, the second semiconductor structure further includes a second semiconductor layer, a second dielectric structure, a third conductive structure and a third connection structure; where the second semiconductor layer is located between the first semiconductor structure and the second dielectric structure, the second dielectric structure covers a step region of the memory array, the third conductive structure is located in the second dielectric structure, and the third connection structure extends through the second semiconductor layer along the first direction; and where the peripheral circuit is coupled to the analog-to-digital conversion circuit through the third conductive structure and the third connection structure.

In some examples, the first semiconductor structure further includes a controller, and a portion of the controller is located in the first semiconductor layer; where the second semiconductor structure further includes a fourth conductive structure and a fourth connection structure, the fourth conductive structure is located in the second dielectric structure, and the fourth connection structure extends through the second semiconductor layer along the first direction; and where the controller is coupled to the peripheral circuit through the fourth connection structure and the fourth conductive structure.

In some examples, the second semiconductor structure further includes a fifth conductive structure and a fifth connection structure, the fifth conductive structure is located in the second dielectric structure, and the fifth connection structure extends through the second semiconductor layer along the first direction; where the controller is further coupled to the peripheral circuit through the fifth connection structure and the fifth conductive structure; and the fifth connection structure and the fourth connection structure are configured to transmit different control signals, respectively.

In some examples, the second semiconductor structure further includes a sixth conductive structure and a sixth connection structure, the sixth conductive structure is located in the second dielectric structure, and the sixth connection structure extends through the second semiconductor layer along the first direction; the third semiconductor structure further includes a third semiconductor layer, a third dielectric structure, a seventh conductive structure, and a seventh connection structure, the third semiconductor layer is located between the pad and the third dielectric structure, and a portion of the peripheral circuit is located in the third semiconductor layer, the third dielectric structure is located between the third semiconductor layer and the second semiconductor structure, and the seventh conductive structure is located in the third dielectric structure, the seventh connection structure extends through the third semiconductor layer along the first direction; where the pad is coupled to the interface circuit through the seventh connection structure, the seventh conductive structure, the sixth conductive structure, and the sixth connection structure.

In some examples, the second semiconductor structure further includes a bit line coupled to the memory array, and the bit line is located between the memory array and the third semiconductor structure; and the third semiconductor structure further includes an eighth conductive structure located in the third dielectric structure, where the peripheral circuit is coupled to the bit line through the eighth conductive structure.

In some examples, the first semiconductor structure further includes a first dielectric structure and a ninth conductive structure; the first dielectric structure is located between the pad and the second semiconductor structure, and the ninth conductive structure is located in the first dielectric structure; the second semiconductor structure further includes a source line coupled to the memory array, and the source line is located between the memory array and the first semiconductor structure; where the ninth conductive structure is coupled to the source line and the analog-to-digital conversion circuit, respectively, and the analog operation result is transmitted to the analog-to-digital conversion circuit through the source line and the ninth conductive structure.

In some examples, a first side of the second semiconductor structure is bonded to the first semiconductor structure, and a second side of the second semiconductor structure is bonded to the third semiconductor structure; where the first side of the second semiconductor structure is opposite to the second side of the second semiconductor structure along the first direction.

In some examples, the memory array includes a three-dimensional NAND type memory array.

According to a second aspect of the examples of the present disclosure, another semiconductor device is provided, including: a first semiconductor structure and a second semiconductor structure sequentially stacked along a first direction; where the first semiconductor structure includes a memory array and a bonding layer; the bonding layer is located on one side, away from the second semiconductor structure, of two opposite sides of the memory array along the first direction; the second semiconductor structure includes a peripheral circuit and a pad; the peripheral circuit is coupled to the memory array; where the pad is located on one side, away from the first semiconductor structure, of two opposite sides of the peripheral circuit along the first direction; and the pad is configured to output an operation result obtained by performing an operation by the memory array.

In some examples, the first semiconductor structure further includes a first semiconductor layer, a first dielectric structure, a first conductive structure, and a first connection structure; where the first semiconductor layer is located between the first bonding layer and the first dielectric structure, the first dielectric structure covers a step region of the memory array, the first conductive structure is located in the first dielectric structure, and the first connection structure extends through the first semiconductor layer along the first direction; and where the peripheral circuit is coupled to the first connection structure through the first conductive structure, and the first connection structure is configured to transmit analog information obtained by performing an operation by the memory array.

In some examples, the first semiconductor structure further includes a second conductive structure and a second connection structure; the second conductive structure is located in the first dielectric structure, and the second connection structure extends through the first semiconductor layer along the first direction; where the peripheral circuit is coupled to the second connection structure through the second conductive structure, and the second connection structure is configured to transmit a first control signal.

In some examples, the first semiconductor structure further includes a third conductive structure and a third connection structure; the third conductive structure is located in the first dielectric structure, and the third connection structure extends through the first semiconductor layer along the first direction; where the peripheral circuit is coupled to the third connection structure through the third conductive structure, and the third connection structure is configured to transmit a second control signal different from the first control signal.

In some examples, the first semiconductor structure further includes a fourth conductive structure and a fourth connection structure; the fourth conductive structure is located in the first dielectric structure, and the fourth connection structure extends through the first semiconductor layer along the first direction; the second semiconductor structure further includes a second semiconductor layer, a second dielectric structure, a fifth conductive structure, and a fifth connection structure; the second semiconductor layer is located between the pad and the second dielectric structure, and a portion of the peripheral circuit is located in the second semiconductor layer; the second dielectric structure is located between the second semiconductor layer and the first semiconductor structure, the fifth conductive structure is located in the second dielectric structure; and the fifth connection structure extends through the second semiconductor layer along the first direction; where the pad is connected to the fourth connection structure through the fifth connection structure, the fifth conductive structure, and the fourth conductive structure.

In some examples, the first semiconductor structure further includes a bit line coupled to the memory array, and the bit line is located between the memory array and the second semiconductor structure; the second semiconductor structure further includes a sixth conductive structure; the sixth conductive structure is located in the second dielectric structure; where the peripheral circuit is coupled to the bit line through the sixth conductive structure.

In some examples, the bonding layer includes a bonding dielectric layer and a bonding contact extending through the bonding dielectric layer along the first direction.

In some examples, the memory array includes a three-dimensional NAND type memory array.

According to a third aspect of the examples of the present disclosure, a method of manufacturing a semiconductor device is provided, including: forming a first semiconductor structure, a second semiconductor structure and a third semiconductor structure sequentially stacked along a first direction; where the first semiconductor structure includes an analog-to-digital conversion circuit and an interface circuit, the second semiconductor structure includes a memory array, the third semiconductor structure includes a peripheral circuit coupled to the memory array and the analog-to-digital conversion circuit, respectively; the analog-to-digital conversion circuit is configured to receive analog information obtained by performing an operation by the memory array; the first semiconductor structure further includes a pad coupled to the interface circuit and located on one side, away from the second semiconductor structure, of two opposite sides of the analog-to-digital conversion circuit along the first direction; or the third semiconductor structure further includes a pad coupled to the interface circuit and located on one side, away from the second semiconductor structure, of two opposite sides of the peripheral circuit along the first direction.

In some examples, the forming the first semiconductor structure, the second semiconductor structure and the third semiconductor structure sequentially stacked along the first direction includes: forming the first semiconductor structure, the second semiconductor structure, and the third semiconductor structure, respectively; bonding a first side of the second semiconductor structure to the first semiconductor structure, and bonding a second side of the second semiconductor structure to the third semiconductor structure; where the first side of the second semiconductor structure is opposite to the second side of the second semiconductor structure along the first direction.

In some examples, the forming the first semiconductor structure includes: forming the interface circuit and the analog-to-digital conversion circuit based on a first semiconductor layer; where both a portion of the analog-to-digital conversion circuit and a portion of the interface circuit are located in the first semiconductor layer; and forming the pad on one side, away from the second semiconductor structure, of two opposite sides of the first semiconductor layer along the first direction.

In some examples, the forming the first semiconductor structure further includes: forming a first connection structure extending through the first semiconductor layer along the first direction; where the pad is coupled to the interface circuit through the first connection structure.

In some examples, the forming the first semiconductor structure further includes: forming a first conductive structure on one side, away from the second semiconductor structure, of two opposite sides of the first semiconductor layer along the first direction, where the first conductive structure is connected to the interface circuit; the forming the pad on one side, away from the second semiconductor structure, of two opposite sides of the first semiconductor layer along the first direction includes: forming the pad on one side, away from the first semiconductor layer, of two opposite sides of the first conductive structure along the first direction, where the pad is connected to the first conductive structure.

In some examples, the forming the third semiconductor structure includes: forming the peripheral circuit based on a third semiconductor layer; where a portion of the peripheral circuit is located in the third semiconductor layer; and forming the pad on one side, away from the second semiconductor structure, of two opposite sides of the third semiconductor layer along the first direction.

According to a fourth aspect of the examples of the present disclosure, a package structure is provided, including: a package substrate, the semiconductor device according to any one of the above examples, and a molding layer; where the semiconductor device is disposed on the package substrate; and the molding layer encapsulates the semiconductor device.

According to a fifth aspect of the examples of the present disclosure, an electronic device is provided, including: a host and the semiconductor device according to any one of the above examples; where the host is coupled to the semiconductor device.

In the examples of the present disclosure, by sequentially stacking the first semiconductor structure including the interface circuit and the analog-to-digital conversion circuit, the second semiconductor structure including the memory array and the third semiconductor structure including the peripheral circuit along the first direction, the pad is integrated in the first semiconductor structure or the third semiconductor structure, and the pad is coupled with the interface circuit. In this way, according to the first aspect, the three-dimensional integration of the semiconductor device can be realized, such that the chip size is reduced, and the memory density is improved; according to the second aspect, a new integrated pad design of the logic chip and the 3D NAND flash memory is provided, which not only realizes the in-memory computing function, but also meets the high bandwidth and high computing power requirements of in-memory computing, providing high-performance and low-cost solutions for large model high computing power hardware.

### BRIEF DESCRIPTION OF THE DRAWINGS

In the drawings, like reference numbers refer to like or similar parts or elements throughout the several drawings unless otherwise specified. These drawings are not necessarily drawn to scale. It should be understood that these drawings depict only some implementations disclosed in accordance with the present disclosure and should not be considered as limiting the scope of the present disclosure.

FIG. 1A is a schematic block diagram of a semiconductor device provided by an example of the present disclosure;

FIG. 1B is a schematic block diagram of another semiconductor device provided by an example of the present disclosure;

FIG. 2 is a schematic block diagram of a memory array and a peripheral circuit provided by an example of the present disclosure;

FIG. 3 is a schematic cross-sectional view of a memory array including a memory string provided by an example of the present disclosure;

FIG. 4 is another schematic block diagram of a peripheral circuit and a memory array provided by an example of the present disclosure;

FIG. 5 is a schematic diagram of inputting an input voltage to a memory array by a top select line provided by an example of the present disclosure;

FIG. 6 is a schematic diagram of a plurality of memory strings coupled to a bit line provided by an example of the present disclosure;

FIG. 7 is a schematic structural diagram of a semiconductor device provided by an example of the present disclosure;

FIG. 8 is a schematic cross-sectional view of a semiconductor device provided by a first example of the present disclosure;

FIG. 9 is a schematic cross-sectional view of a semiconductor device provided by a second example of the present disclosure;

FIG. 10 is a schematic cross-sectional view of a semiconductor device provided by a third example of the present disclosure;

FIG. 11 is a schematic cross-sectional view of a semiconductor device provided by a fourth example of the present disclosure;

FIG. 12 is another schematic cross-sectional view of a semiconductor device provided by an example of the present disclosure;

FIG. 13 is a flowchart of a method of manufacturing a semiconductor device provided by an example of the present disclosure;

FIG. 14A to FIG. 14D are schematic diagrams of a manufacturing process of a semiconductor device provided by a first example of the present disclosure;

FIG. 15A to FIG. 15D are schematic diagrams of a manufacturing process of a semiconductor device provided by a second example of the present disclosure;

FIG. 16A to FIG. 16D are schematic diagrams of a manufacturing process of a semiconductor device provided by a third example of the present disclosure;

FIG. 17 is a schematic diagram of a package structure provided by an example of the present disclosure;

FIG. 18 is a schematic diagram of an example electronic device having a semiconductor device provided by an example of the present disclosure;

FIG. 19 is a schematic diagram of an example memory card having a semiconductor device provided by an example of the present disclosure; and

FIG. 20 is a schematic diagram of an example solid state disk having a semiconductor device provided by an example of the present disclosure.

### DETAILED DESCRIPTION

For ease of understanding of the present disclosure, example implementations disclosed in the present disclosure will be described in more detail below with reference to the accompanying drawings. Although example implementations of the present disclosure are shown in the accompanying drawings, it should be understood that the present disclosure may be implemented in various forms and should not be limited to the example implementations set forth herein. Rather, these implementations are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In some examples, in order to avoid confusion with the present disclosure, some technical features well-known in the art are not described; that is, not all features of the actual example may be described here, and well-known functions and structures are not described in detail.

In general, the terms may be understood at least in part from the use in the context. For example, depending at least in part on context, the term “one or more” as used herein may be used to describe any feature, structure, or characteristic in a singular sense, or may be used to describe a combination of features, structures, or characteristics in a plural sense. Similarly, the terms such as “a” or “the” may likewise be understood to convey singular usage or convey complex usage, depending at least in part on context. In addition, the term “based on” may be understood to not necessarily be intended to convey an exclusive set of factors, and may instead allow for the presence of additional factors that are not necessarily explicitly described, again depending at least in part on the context.

Unless otherwise defined, terms used herein is for the purpose of describing a particular example only and is not to be considered as limitation of the present disclosure. As used herein, the singular forms “a,” “an” and “said/the” are intended to comprise the plural forms as well, unless the context clearly dictates otherwise. It should also be understood that the terms “consists of” and/or “comprising,” when used in this description, identify the presence of stated features, integers, operations, elements and/or parts, but do not exclude the presence or addition of one or more other features, integers, operations, elements, parts and/or groups. As used herein, the term “and/or” comprises any and all combinations of the associated listed items.

For a thorough understanding of the present disclosure, detailed steps and detailed structures will be presented in the following description in order to set forth the technical solutions of the present disclosure. Preferred examples of the present disclosure are described in detail below, however, the present disclosure may have other implementations in addition to these detailed descriptions.

In the classical von Neumann computing architecture, the memory device is separate from the processor, and the data is transmitted between the memory device and the processor through the data bus. When executing the command, the processor first reads the data from the memory device, and then writes the updated data back to the memory device after being processed, and frequent data migration brings huge power consumption and time overhead; in addition, since the bandwidth of the memory device is limited, the processing speed of the processor is limited by the access speed of the memory device, which greatly affects the computing performance. With the rise of applications such as big data and artificial intelligence, especially the advent of the generative artificial intelligence big language model, the scale of the AI model and related computing requirements increase dramatically, and massive data processing creates the bottleneck of the von Neumann computing architecture more and more prominent.

In order to solve the bottleneck of the classical von Neumann computing architecture, the compute-in-memory chip architecture emerges, and the basic idea thereof is to embed a computing function in the memory device, and directly use the memory device to perform logic computing, thereby reducing the data transmission amount and the transmission distance between the memory device and the processor, improving the computing performance while reducing the power consumption, and thus, it is expected to build computing systems with high computing power, high bandwidth, and high energy efficiency.

The compute-in-memory chip has both memory and computing capabilities based on its own physical characteristics. The memory capability refers to the ability of different memory devices to store values by changing their conductance values according to their physical characteristics, and the computing capability refers to the ability to complete the multiplication calculation of a vector and a matrix within a certain time according to Ohm's law and Kirchhoff's law by constructing an array composed of memory devices. The compute-in-memory chip includes, but is not limited to, a static random access memory (SRAM), a NAND flash memory, and a dynamic random access memory (DRAM). NAND flash memory is a non-volatile memory and has a large capacity, thus becoming a widely studied object in the compute-in-memory chip.

In view of the extremely high memory density of the 3D NAND memory array, the 3D NAND memory array can be configured to carry large model weights and apply in-memory computing for big model inference. In order to meet the high bandwidth and high computing power requirements of in-memory computing, the manner in which the logic chip and the 3D NAND flash memory are integrated needs to be specially designed to provide high-performance and low-cost solutions for large model computing power hardware.

Based on one or more of the above technical problems, an example of the present disclosure provides a semiconductor device.

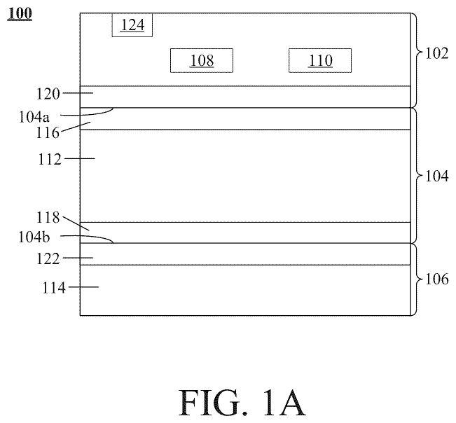

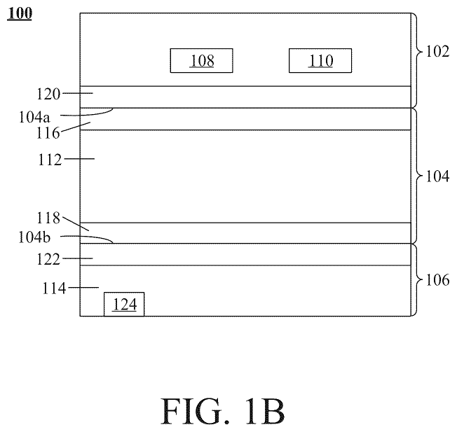

FIG. 1A is a schematic block diagram of a semiconductor device provided by an example of the present disclosure, and FIG. 1B is a schematic block diagram of another semiconductor device provided by an example of the present disclosure. Referring to FIG. 1A and FIG. 1B, the semiconductor device 100 includes a first semiconductor structure 102, a second semiconductor structure 104, and a third semiconductor structure 106 sequentially stacked along a first direction; where a first side 104a of the second semiconductor structure 104 is bonded to the first semiconductor structure 102, and a second side 104b of the second semiconductor structure 104 is bonded to the third semiconductor structure 106.

Referring to FIG. 1A and FIG. 1B, the first side 104a of the second semiconductor structure 104 and the second side 104b of the second semiconductor structure 104 are opposite to each other along the first direction, the third semiconductor structure 106 and the first semiconductor structure 102 are integrated on two opposite sides of the second semiconductor structure 104 along the first direction, respectively, so that the first semiconductor structure 102, the second semiconductor structure 104 and the third semiconductor structure 106 are located in different planes, respectively; that is, the first semiconductor structure 102, the second semiconductor structure 104 and the third semiconductor structure 106 are sequentially stacked along the first direction. In this way, the planar size of the semiconductor device 100 can be reduced, the integration level can be improved, and the memory density can be increased.

In some examples, the first semiconductor structure 102, the second semiconductor structure 104, and the third semiconductor structure 106 may be formed on different substrates, respectively. For example, the first semiconductor structure 102 is formed on a first substrate, the second semiconductor structure 104 is formed on a second substrate, and the third semiconductor structure 106 is formed on a third substrate, which are stacked on each other using various bonding techniques such as hybrid bonding, transfer bonding, and the like.

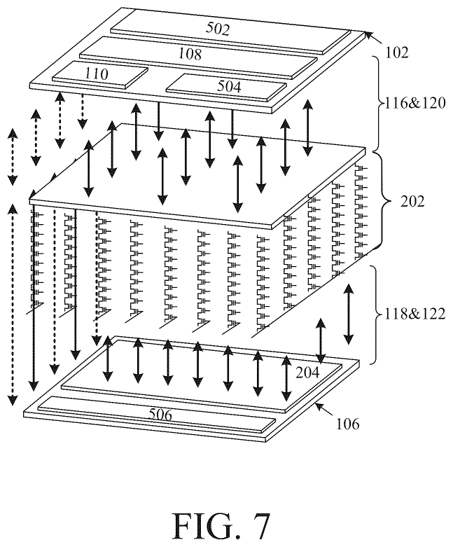

The first semiconductor structure 102 includes an analog-to-digital conversion circuit 108 configured to convert an analog signal into a digital signal and transmit the digital signal to a data processing circuit (e.g., a data processing circuit 502 in FIG. 7). The analog-to-digital conversion circuit 108 includes, but is not limited to, an analog-to-digital converter (ADC).

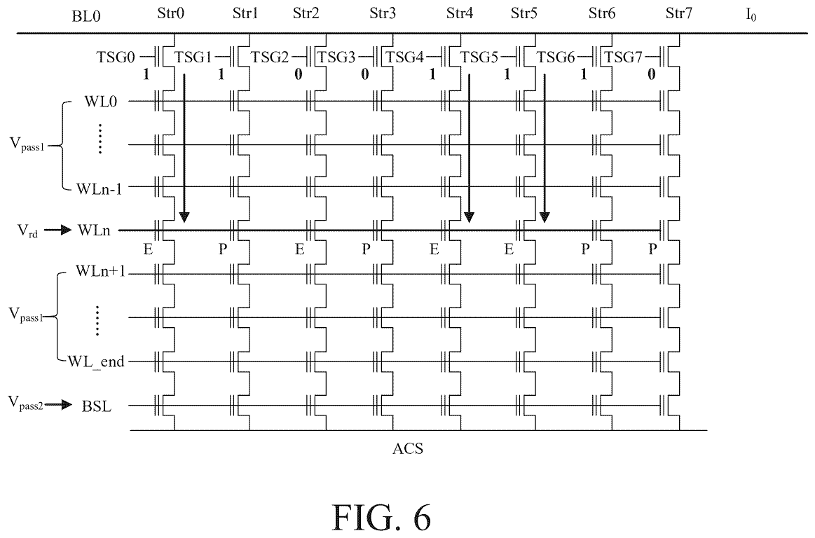

As an example, the analog-to-digital conversion circuit 108 is configured to receive analog information obtained by performing an operation (for example, a first operation) on the memory array 112 in the second semiconductor structure 104, convert the analog computing information into digital information, and transmit the digital information to the data processing circuit. In this example, the first operation includes a multiply-accumulate operation, for example, in FIG. 6, the multiply-accumulate operation may be performed on eight memory strings coupled to the same bit line BL0 based on characteristics of the NAND itself, and a sum of output currents of eight memory strings coupled to the bit line BL0 (that is, the current I₀ on the bit line BL0) may be equivalent to a result of the multiply-accumulate operation, and a process of the multiply-accumulate operation may be referred to the related description of FIG. 6.

It should be noted that both the analog-to-digital conversion circuit 108 and the data processing circuit may be located in the first semiconductor structure 102; that is, the first semiconductor structure 102 includes the analog-to-digital conversion circuit 108 and the data processing circuit. However, in other examples, the data processing circuit may be located in other semiconductor structures, for example, the data processing circuit is formed on another substrate, and is bonded to the first substrate on which the analog-to-digital conversion circuit 108 is formed, thereby realizing the connection between the analog-to-digital conversion circuit 108 and the data processing circuit.

The first semiconductor structure 102 also includes an interface circuit 110 configured to receive and transmit data between the semiconductor device 100 and other external device (e.g., host). In an example, the interface circuit 110 is configured to output the operation result after the data processing circuit performs the second operation to the external device. The interface protocol may serve as an interface circuit 110 between the semiconductor device 100 and the external device, and as such, the semiconductor device 100 may communicate with the external device through at least one of various interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Fire wire protocol, and the like. The interface circuit 110 herein may also be referred to as a front-end interface.

The second semiconductor structure 104 includes a memory array 112, which may perform a first operation to obtain simulation computing information, which may be transmitted to the analog-to-digital conversion circuit 108. The memory array 112 includes, but is not limited to, a three-dimensional NAND type memory array.

The third semiconductor structure 106 includes a peripheral circuit 114 coupled to the memory array 112 and the analog-to-digital conversion circuit 108, respectively. The peripheral circuit 114 may control the memory array 112 to perform an in-memory computing operation, a program operation, a read operation, an erase operation, and the like.

As an example, the peripheral circuit 114 may control the memory array 112 to perform an in-memory computing operation, and control the memory array 112 to transmit the simulation computing information obtained by performing the in-memory computing operation to the analog-to-digital conversion circuit 108.

In some examples, the first semiconductor structure further includes a pad coupled to the interface circuit and located on one side, away from the second semiconductor structure, of two opposite sides of the analog-to-digital conversion circuit along the first direction; or the third semiconductor structure further includes a pad coupled to the interface circuit and located on one side, away from the second semiconductor structure, of two opposite sides of the peripheral circuit along the first direction.

As an example, referring to FIG. 1A, the first semiconductor structure 102 further includes a pad 124, and the pad 124 is exposed on a surface of two opposite surfaces of the first semiconductor structure 102 along the first direction away from the second semiconductor structure 104, thereby facilitating electrical connection between the external device and the pad 124. It may be understood that in this example, the pad 124 is formed on the first semiconductor structure 102, and the pad 124 may be coupled to the interface circuit 110 through wiring inside the first semiconductor structure 102.

As another example, referring to FIG. 1B, the third semiconductor structure 106 further includes a pad 124, and the pad 124 is exposed on a surface of two opposite surfaces of the third semiconductor structure 106 along the first direction away from the second semiconductor structure 104, thereby facilitating electrical connection between the external device and the pad 124. It may be understood that in this example, the pad 124 is formed on the third semiconductor structure 106, and the pad 124 may be coupled to the interface circuit 110 through the wiring inside the third semiconductor structure 106, the wiring inside the second semiconductor structure 104, and the wiring inside the first semiconductor structure, and the like.

The material of the pad 124 includes a conductive material, such as at least one of a doped-semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In the above two examples, the pad 124 may serve as a physical interface for connecting the semiconductor device 100 and the external device, for example, a signal may be transmitted between the host and the semiconductor device 100 through the pad 124. It should be noted that the interface circuit 110 may serve as a “logic layer” for communication between the semiconductor device 100 and the external device, and is responsible for protocol analysis and data management; and the pad 124 serves as a “physical layer” for connecting the semiconductor device 100 and the external device, to ensure electrical connection between the components. The cooperative work of the logic layer and the physical layer can ensure efficient and stable operation of the semiconductor device 100.

In the examples of the present disclosure, by sequentially stacking the first semiconductor structure including the interface circuit and the analog-to-digital conversion circuit, the second semiconductor structure including the memory array and the third semiconductor structure including the peripheral circuit along the first direction, the pad is integrated in the first semiconductor structure or the third semiconductor structure, and the pad is coupled with the interface circuit. In this way, according to the first aspect, the three-dimensional integration of the semiconductor device can be realized, such that the chip size is reduced, and the memory density is improved; according to the second aspect, a new integrated pad design of the logic chip and the 3D NAND flash memory is provided, which not only realizes the in-memory computing function, but also meets the high bandwidth-requirement and high computing-power requirement of in-memory computing, providing high-performance and low-cost solutions for large model high computing power hardware.

In some examples, the first semiconductor structure 102 and the second semiconductor structure 104 may be vertically connected through bonding, and the second semiconductor structure 104 and the third semiconductor structure 106 may be vertically connected through bonding. As an example, referring to FIG. 1A or FIG. 1B, the second semiconductor structure 104 includes a first bonding layer 116 and a second bonding layer 118 disposed opposite to each other along the first direction, the first semiconductor structure 102 includes a third bonding layer 120, and the third semiconductor structure 106 includes a fourth bonding layer 122.

The first bonding layer 116 and the third bonding layer 120 are bonded such that the first semiconductor structure 102 and the second semiconductor structure 104 are vertically connected. In the first semiconductor structure 102 and the second semiconductor structure 104, which are bonded, the first bonding layer 116 is located between the first semiconductor structure 102 and the memory array 112, and the third bonding layer 120 is located between the analog-to-digital conversion circuit 108 and the first bonding layer 116.

The second bonding layer 118 and the fourth bonding layer 122 are bonded such that the second semiconductor structure 104 and the third semiconductor structure 106 are vertically connected. In the second semiconductor structure 104 and the third semiconductor structure 106, which are bonded, the second bonding layer 118 is located between the third semiconductor structure 106 and the memory array 112, and the fourth bonding layer 122 is located between the peripheral circuit 114 and the second bonding layer 118.

It should be noted that the above bonding connection includes a hybrid bonding connection (also referred to as a “metal/dielectric hybrid bonding connection”), which is a direct bonding technique, such as forming the bonding between the surfaces without using an intermediate layer such as a solder or an adhesive, and can simultaneously obtain a metal-metal bonding and a dielectric-to-dielectric bonding. It should be noted that the “bonding” mentioned in the present disclosure may be any appropriate bonding technique, such as the hybrid bonding, anodic bonding, fusion bonding, transfer bonding, adhesive bonding, and eutectic bonding mentioned above, and the like.

In some examples, the semiconductor device 100 further includes a first bonding interface between the first bonding layer 116 and the third bonding layer 120, and a second bonding interface between the second bonding layer 118 and the fourth bonding layer 122. Data transfer between the first semiconductor structure 102 and the second semiconductor structure 104 may be achieved by interconnects (e.g., bonding contacts) across the first bonding interface. Data transfer between the second semiconductor structure 104 and the third semiconductor structure 106 may be achieved by interconnects (e.g., bonding contacts) across the second bonding interface.

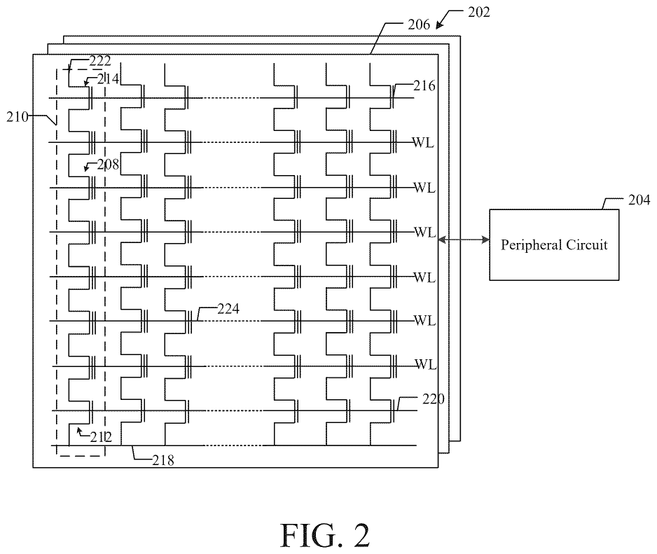

FIG. 2 is a schematic block diagram of a memory array and a peripheral circuit provided by an example of the present disclosure, and for ease of understanding, taking an example in which the memory array 202 is a three-dimensional NAND type memory array for description, where the memory cell 208 is a NAND memory cell, the memory cell 208 is provided in a form of an array of memory strings 210, and each memory string 210 extends vertically. In some examples, each memory string 210 includes a plurality of memory cells 208 coupled in series and stacked vertically. Each memory cell 208 may maintain a continuous analog value, e.g., voltage or charge, depending on the number of electrons captured within the area of the memory cell 208. Each memory cell 208 may be a floating gate type of memory cell including a floating gate transistor, or a charge trapping type of memory cell including a charge trapping transistor.

In some examples, each memory cell 208 is a single level cell (SLC) having two possible memory states and thus may store one bit of data. For example, the first memory state “0n” may correspond to a first voltage range and the second memory state “1” may correspond to a second voltage range. In some other examples, each memory cell 208 is a multi-level cell capable of storing more than a single bit of data in four or more memory states, e.g., a multi-level cell (MLC) storing two bits per cell, a triple level cell (TLC) storing three bits per cell, or a quad-level cell (QLC) storing four bits per cell.

Referring to FIG. 2, each memory string 210 may include a bottom select transistor (bottom select bate, BSG) 212 at its source terminal and a top select transistor (top select gate, TSG) 214 at its drain terminal. The bottom select transistor 212 and the top select transistor 214 may be configured to activate the selected memory string 210 during read and program operations. In some examples, the source terminals of the memory strings 210 in the same memory block 206 may be coupled through a common source line (CSL) 218. In other words, all the memory strings 210 in the same memory block 206 have an array common source (ACS). According to some implementations, the top select transistor 214 of each memory string 210 is coupled to a respective bit line 222 from which data may be read or written via an output bus (not shown). In some examples, each memory string 210 is configured to be selected or deselected by applying a select voltage (e.g., a voltage higher than a threshold voltage of the top select transistor 214) or a deselect voltage (e.g., 0V) to the respective top select transistor 214 through one or more top select lines (TSL) 216 and/or applying a select voltage (e.g., a voltage higher than a threshold voltage of the bottom select transistor 212) or a deselect voltage (e.g., 0V) to the respective bottom select transistor 212 through one or more bottom select lines (BSL) 220.

Referring to FIG. 2, the memory string 210 may be organized into a plurality of memory blocks 206, each of which may have a common source line 218. In some examples, each memory block 206 is a basic data unit for an erase operation, e.g., all memory cells 208 on the same memory block 206 are erased simultaneously. To erase the memory cells 208 in the selected memory block, a common source line 218 coupled to the selected memory block and unselected memory blocks in the same plane as the selected memory block may be biased with an erase voltage. It should be understood that in some examples, the erase operation may be performed at a half-memory block level, a quarter-memory block level, or a level having any suitable number of memory blocks or any suitable fractions of a memory block. The memory cells 208 of adjacent memory strings 210 may be coupled through word lines 224 that select which row of memory cells 208 is affected by read and program operations.

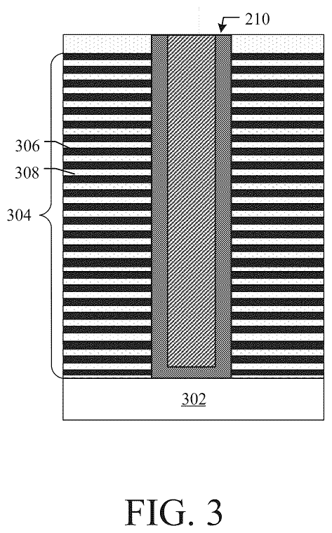

FIG. 3 is a schematic cross-sectional view of a memory array including a memory string provided by an example of the present disclosure. Referring to FIG. 3, a stack structure 304 includes a plurality of gate layers 306 and a plurality of insulating layers 308 alternately stacked, and a memory string 210 extending through the gate layer 306 and the insulating layer 308. The gate layer 306 and the insulating layer 308 may be alternately stacked, and two adjacent gate layers 306 are separated by one insulating layer 308. The number of memory cells included in the memory array is mainly related to the number of pairs of gate layers 306 and insulating layers 308 in the stack structure 304.

The composition material of the gate layer 306 may include a conductive material. The conductive material includes, but is not limited to, tungsten, cobalt, copper, aluminum, polysilicon, doped silicon, silicide, or any combination thereof. In some examples, each gate layer 306 includes a metal layer, such as a tungsten layer. In some examples, each gate layer 306 includes a doped polysilicon layer. Each gate layer 306 may include a control gate surrounding the memory cell. The gate layer 306 at the top of the stack structure 304 may extend laterally as a top select line, the gate layer 306 at the bottom of the stack structure 304 may extend laterally as a bottom select line, and the gate layer 306 extending laterally between the top select line and the bottom select line may serve as a word line layer.

In some examples, the stack structure 304 may be disposed on the semiconductor layer 302. The semiconductor layer 302 may include silicon, silicon germanium, gallium arsenide, germanium, silicon on insulator, germanium on insulator, or any other suitable material. In some other examples, the semiconductor device may not include the semiconductor layer.

In some examples, the memory string 210 includes a channel structure that extends vertically through the stack structure 304. In some examples, the channel structure includes a channel hole filled with a semiconductor material(s) (e.g., as a semiconductor channel) and a dielectric material(s) (e.g., as a memory film). In some examples, the semiconductor channel includes silicon, e.g., polysilicon. In some examples, the memory film is a composite dielectric layer including a tunneling layer, a storage layer (also referred to as a “charge trapping/storage layer”), and a blocking layer. The channel structure may have a cylindrical shape (e.g., a pillar shape). According to some implementations, the semiconductor channel, the tunneling layer, the storage layer, and the blocking layer are arranged radially from the center of the pillar toward the outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

Referring back to FIG. 2, a peripheral circuit 204 may be coupled to a memory array 202 through a bit line 222, a word line 224, a source line 218, a bottom select line 220, and a top select line 216. The peripheral circuit 204 may include any suitable analog, digital, and mixed-signal circuit for facilitating operation of the memory array 202 by applying at least one of voltage signals or current signals to and sensing at least one of voltage signals or current signals from each of the target memory cells 208 via the bit line 222, the word line 224, the source line 218, the bottom select line 220, and the top select line 216. The peripheral circuit 204 may include various types of peripheral circuits formed using metal-oxide-semiconductor technology.

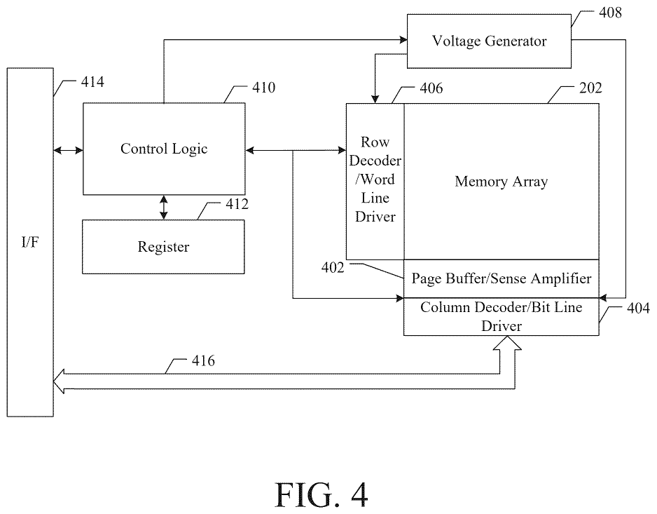

FIG. 4 is another schematic block diagram of a peripheral circuit and a memory array provided by an example of the present disclosure. The peripheral circuit may include a page buffer/sense amplifier 402, a column decoder/bit line driver 404, a row decoder/word line driver 406, a voltage generator 408, a register 412, and a data bus 416. It should be understood that in some examples, additional peripheral circuits not shown in FIG. 4 may also be included.

A control logic 410 may be coupled to each peripheral circuit described above and configured to control operation of each peripheral circuit. The register 412 may be coupled to the control logic 410 and include a status register, a command register, and an address register for storing status information, command operation code (OP code), and command addresses for controlling operation of each peripheral circuit.

The page buffer/sense amplifier 402 may be configured to read data from and program (write) data to the memory array 202 according to control signals from the control logic 410. In one example, the page buffer/sense amplifier 402 may store program data (write data) to be programmed to the memory cells 208 of the memory array 202. In another example, the page buffer/sense amplifier 402 may perform a program verify operation to ensure that the data has been properly programmed into the memory cell 208 coupled to the selected word line 224. The column decoder/bit line driver 404 may be configured to be controlled by the control logic 410 and select one or more NAND memory strings 210 by applying a bit line voltage generated from voltage generator 408.

The row decoder/word line driver 406 may be configured to be controlled by the control logic 410 and select/deselect the memory block 206 of the memory array 202 and select/deselect the word line 224 of the memory block 206. The row decoder/word line driver 406 may also be configured to drive the word line 224 using the word line voltage generated from the voltage generator 408. In some implementations, the row decoder/word line driver 406 may also select/deselect and drive the bottom select line 220 and the top select line 216. As described in detail below, the row decoder/word line driver 406 is configured to perform a program operation by the memory cells 208 coupled to the selected word line(s) 224. The voltage generator 408 may be configured to be controlled by the control logic 410 and generate a word line voltage (e.g., a read voltage, a program voltage, a pass voltage, a local voltage, a verify voltage, an input voltage, etc.), a bit line voltage, and a source line voltage to be supplied to the memory array 202.

In some examples, for a compute-in-memory chip, a first operation of input data and a weight matrix needs to be implemented, the input data may be an input vector or an input matrix composed of a plurality of elements, the weight matrix is composed of a plurality of weights, and a multiply-accumulate operation needs to performed on each element in the input data and a plurality of weights in the weight matrix to obtain a corresponding element in the output data.

To implement the above operation functions, the memory array 202 may be configured to store a weight matrix, and in an example, weights in the weight matrix may be written into the memory array 202 according to a certain mapping rule, and each memory cell 208 in the memory array 202 may be configured to store a weight. In the operation phase, the second semiconductor structure 104 in FIG. 1 may receive input data from an external device, the input data may be an input vector or an input matrix composed of a plurality of elements, and each element in the input data may be converted into an input voltage by the digital-to-analog conversion circuit, and input to the memory array 202 by the bit line 222 or the word line 224.

In the examples of the present disclosure, the analog computing information may be output via a bit line, or via a source terminal. That is, the bit line in the second semiconductor structure is the output terminal of the analog information, or the source terminal is the output terminal of the analog information. For ease of understanding, the following takes an example in which a bit line is the output terminal of the analog information for illustration.

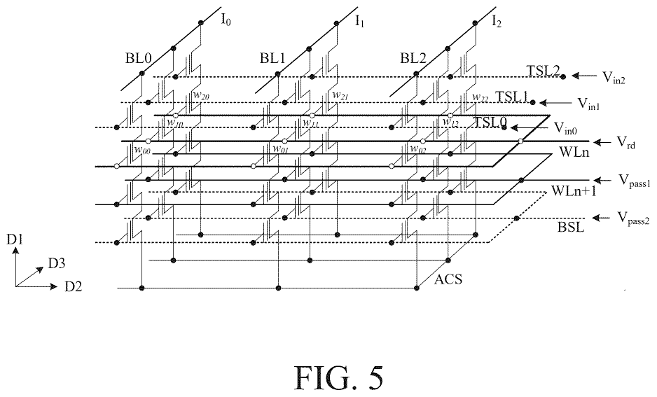

FIG. 5 is a schematic diagram of inputting an input voltage to a memory array by a top select line provided by an example of the present disclosure, and FIG. 6 is a schematic diagram of a plurality of memory strings coupled to a bit line provided by an example of the present disclosure. It should be noted that the numbers of the bit lines shown in FIG. 5 and FIG. 6, the number of the memory strings coupled to each bit line, and the number of the memory cells in each memory string are merely examples, and the number of the structures is not limited in the present disclosure. The process of the first operation is described below with reference to FIG. 5 and FIG. 6 by taking an example in which a bit line is the output terminal of the analog information.

Referring to FIG. 5, an input voltage corresponding to an element in the input data may be input by a plurality of top select lines. During the first operation phase by using the memory array, the peripheral circuit is configured to: apply a first read voltage V_{rd} to the target word line WLn coupled to the target memory block, and apply a corresponding input voltage to a plurality of top select lines coupled to the target memory block; for example, the input voltages Vᵢₙ₀, Vᵢₙ₁, Vᵢₙ₂ may be applied to the top select lines TSL0, TSL1, TSL2 coupled to the target memory block, respectively, and a first turn-on voltage may be applied to the non-target word lines coupled to the target memory block; for example, a first turn-on voltage Vₚₐₛₛ₁ may be applied to the word line WLn+1, and a second turn-on voltage may be applied to the bottom select line coupled to the target memory block, for example, a second turn-on voltage Vₚₐₛₛ₂ may be applied to the bottom select line BSL.

The analog computing information may be obtained by sensing the current on the bit line coupled to the target memory block, for example, the sum of the product of the element corresponding to the input voltage Vᵢₙ₀ and the weight w₀₀, the product of the element corresponding to the input voltage Vᵢₙ₁ and the weight w₁₀, and the product of the element corresponding to the input voltage Vᵢₙ₂ and the weight w₂₀ may be obtained by sensing the current I₀ on the bit line BL0 and converting the current I₀. In some examples, the first operation includes a multiply-accumulate operation.

In some examples, the peripheral circuit is configured to: apply a respective program voltage to a target word line coupled to the target memory block to program the memory cells coupled to the target word line before performing the first operation using the memory array.

In an example, the memory cell in the target memory block is configured to store one bit of data, the plurality of memory cells in the target memory block have a first memory state and a second memory state, the threshold voltage of the memory cell having the first memory state is less than the threshold voltage of the memory cell having the second memory state, the first read voltage V_{rd} is greater than the threshold voltage of the memory cell having the first memory state, and is less than the threshold voltage of the memory cell having the second memory state. Here, the memory cell in the target memory block may be a single level cell SLC storing one bit of data, the first memory state may be an erase state E, and the second memory state may be a program state P. The peripheral circuit may be configured to perform a program operation on the memory cells coupled to the target word line before performing the first operation, and write the weight to the memory cell according to a certain mapping rule; and for the single level cell, the process of writing the weight includes applying a respective program voltage to adjust a threshold voltage of a portion of the memory cells coupled to the target word line to be within a range of a threshold voltage distribution corresponding to the second memory state.

In some examples, referring to FIG. 6, taking an example in which the target memory block includes eight memory strings coupled to the bit line BL0 for illustration, four memory cells in the memory cells coupled to the target word line WLn are in the first memory state (erase state E), the other four memory cells are in the second memory state (program state P), the input data may be input from the eight top select lines TSL0 to TSL7 and in an example, the input data may be an input vector including eight elements.

The eight elements may include five “1” and three “0,” the digital-to-analog conversion circuit may convert each element of the input vector into a corresponding voltage signal, and convert the voltage signal into an input voltage that needs to be applied on the top select line through the voltage generator 408 shown in FIG. 4, and transfer the input voltage to the top select line through the driver coupled to the top select line. In an example, eight input voltages may be simultaneously applied to the eight top select lines.

The input voltage corresponding to “1” includes Vᵢₙ₀, Vᵢₙ₁, Vᵢₙ₄, Vᵢₙ₅ and Vᵢₙ₆, so that the top select transistors TSG0, TSG1, TSG4, TSG5 and TSG6 coupled to the top select lines TSL0, TSL1, TSL4, TSL5, and TSL6, respectively, may be turned on, and the input voltage corresponding to “0” includes Vᵢₙ₂, Vᵢₙ₃ and Vᵢₙ₇, so that the top select transistors TSG2, TSG3 and TSG7 coupled to the top select lines TSL2, TSL3 and TSL7, respectively, are turned off.

In an example, referring to FIG. 6, the current I₀ on the bit line BL0 is the sum of the output currents of the eight memory strings coupled to the bit line BL0, where the input voltages on the top select lines coupled to the memory strings Str0, Str4 and Str5 causes the top select transistors TSG0, TSG4 and the TSG5 to be in the turn-on state, and the memory cells in the memory strings Str0, Str4, and Str5 coupled to the target word line WLn have the first memory state (erase state E); and thus the memory strings Str0, Str4, and Str5 are turned on, a current greater than or equal to the preset current may be generated, the current I₀ on the bit line BL0 is substantially equal to the sum of the output currents of the memory strings Str0, Str4 and Str5, and the multiple of the current I₀ with respect to the current generated by any one of the memory strings Str0, Str4 and Str5 is about equal to three.

If the weight value stored in the memory cell in the first memory state is equivalent to “1,” and the weight value stored in the memory cell in the second memory state is equivalent to “0,” then the operations performed by the eight memory strings coupled to the bit line BL0 may be equivalent to: 1×1+1×0+0×1+0×0+1×1+1×1+1×0+0×0=3.

Based on the above example, when the number of memory strings coupled to the bit line BLx in the target memory block is Y+1, the Y+1 elements corresponding to the input voltages input by the Y+1 top select lines are α₀, α₁. . . α_{Y}, and the weights stored in the Y+1 memory cells coupled to the target word line WLn are w₀, w₁ . . . w_{Y}, then the analogy computing information equivalent to the multiple of the current on the bit line BLx with respect to the output current greater than or equal to the preset current may be α_{0*}w₀+α_{1*w1}+. . . +α_{Y*wY}.

FIG. 7 is a schematic structural diagram of a semiconductor device provided by an example of the present disclosure. It should be noted that FIG. 7 takes an example in which a bit line is the output terminal of the analog signal for illustration. Referring to FIG. 7, the first semiconductor structure 102 further includes a data processing circuit 502 and a controller 504.

The data processing circuit 502 is configured to perform a second operation on the digital information. The second operation includes one or more of compensation, activation, shift, or pooling operations. The data processing circuit includes a processor, and the processor may include a special purpose processor, including but not limited to a central processing unit (CPU), a graphics processing unit (GPU), a digital signal processor (DSP), a tensor processing unit (TPU), a video processing unit (VPU), a neural processing unit (NPU), a secure processing unit (SPU), a physical processing unit (PPU), and an image signal processor (ISP).

In an example, the data processing circuit is an NPU. The NPU may perform operations such as arithmetic/logical operation, rotation and shift operation, compensation operation, activation operation and pooling operation, and the like. In some examples, the activation operation may be implemented by an activation function stored in the NPU, which may include, but is not limited to, a step function, a correction function, a sigmoid function, a hyperbolic tangent (tanh) function, and a softplus function (also referred to as smooth correction).

The controller 504 may be configured to control operation of the semiconductor device 100. That is, the controller 504 may act as a memory controller that manages data storage and transmission in the second semiconductor structure 104 and the third semiconductor structure 106 which are bonded (hereinafter referred to as bonded semiconductor structures) and an operation controller that manages data operation and transmission in the first semiconductor structure 102. It should be noted that the process node corresponding to the first semiconductor structure 102 may be smaller than the process node corresponding to the third semiconductor structure 106. In this example, by integrating the controller 504 into the first semiconductor structure 102 with a smaller process node and bonding to the bonded semiconductor structure, the planar size of the semiconductor device can be reduced, the integration level can be improved, and the data transmission rate can further be improved.

In some examples, the controller 504 is coupled to the bonded semiconductor structure and an external device (e.g., a host), and is configured to control the bonded semiconductor structure. The controller 504 may manage data stored in the bonded semiconductor structure and communicate with the external device. For example, the controller 504 is further configured to control data transmission between the first semiconductor structure 102 and the bonded semiconductor structure. For another example, the controller 504 is further configured to receive the input data sent by the external device, and send the input data to the bonded semiconductor structure. Certainly, in other examples, a portion or all of the host may be integrated into the first semiconductor structure 102, for example, the host processor may be integrated in the first semiconductor structure, and the like.

In some examples, the controller 504 may also be configured to manage various functions regarding data stored in or to be stored in a bonded semiconductor structure, including, but not limited to, bad block management, garbage collection, logical-to-physical address translation, wear leveling, and the like. In some examples, the controller 504 is further configured to process error correction code (ECC) regarding data read from or written to the bonded semiconductor structure. In some examples, the controller 504 may also perform any other suitable function, such as formatting the bonded semiconductor structure.

In some examples, the controller 504 performs command/data interaction with the bonded semiconductor structure through a plurality of configured channels, which are also referred to as back-end interfaces.

In some examples, the third semiconductor structure 106 further includes an interface circuit 506 (e.g., the second interface circuit 506); the third semiconductor structure 106 may be connected to the first semiconductor structure 102 through the second interface circuit 506. That is, the second interface circuit 506 herein is an interface coupled to the back-end interface of the controller 504; and/or the second interface circuit 506 may also be an interface for communication between the third semiconductor structure 106 and the first semiconductor structure 102.

The second interface circuit 506 may be coupled to the control logic 410 (see FIG. 4) in the peripheral circuit 204 and act as a control buffer to buffer control commands received from the host (not shown) and relay them to the control logic 410 and buffer status information received from the control logic 410 and relay it to the host. The second interface circuit 506 may also be coupled to the column decoder/bit line driver 404 in FIG. 4 via the data bus 416 in FIG. 4 and act as a data I/O interface and a data buffer to buffer data and relay it to the memory array or buffer or relay data from the memory array.

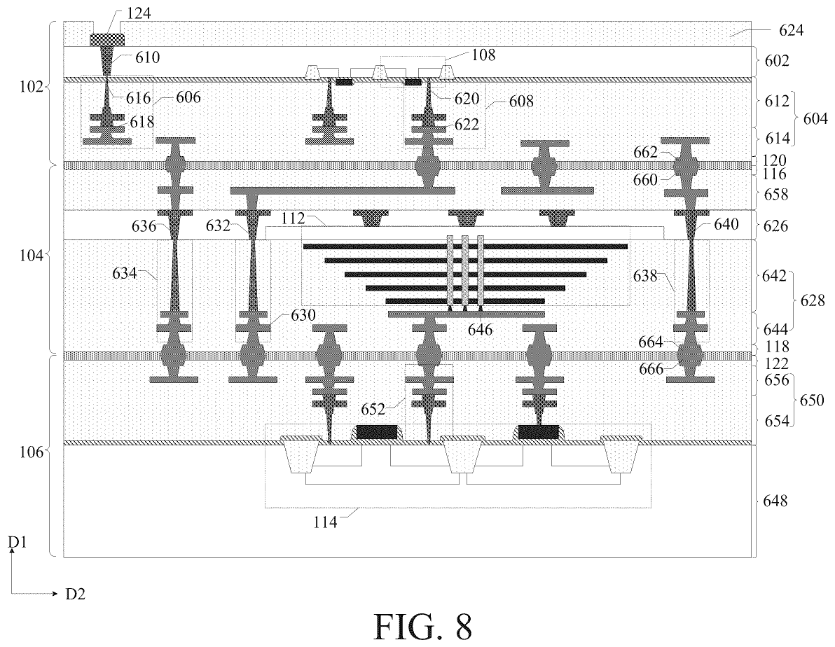

FIG. 8 is a schematic cross-sectional view of a semiconductor device provided by a first example of the present disclosure. Referring to FIG. 1A and FIG. 8, the semiconductor device includes a first semiconductor structure 102, a second semiconductor structure 104, and a third semiconductor structure 106 sequentially stacked along a first direction; the first semiconductor structure 102 includes an analog-to-digital conversion circuit 108 and an interface circuit 110, the second semiconductor structure 104 includes a memory array 112, the third semiconductor structure 106 includes a peripheral circuit 114 coupled to the memory array 112 and the analog-to-digital conversion circuit 108, respectively; the analog-to-digital conversion circuit 108 is configured to receive analog information obtained by performing an operation by the memory array 112; and the first semiconductor structure 102 further includes a pad 124 coupled to the interface circuit 110 and located on one side of two opposite sides of the analog-to-digital conversion circuit 108 along the first direction away from the second semiconductor structure 104. It should be noted that the first direction herein may be the direction D1 in the drawings, and the second direction hereinafter may be the direction D2 in the drawings, and the direction D1 is perpendicular to the direction D2.

In some examples, referring to FIG. 1A and FIG. 8, the first semiconductor structure 102 further includes a first semiconductor layer 602; the first semiconductor layer 602 is located between the pad 124 and the second semiconductor structure 104, and both a portion of the analog-to-digital conversion circuit 108 and a portion of the interface circuit 110 are located in the first semiconductor layer 602.

The first semiconductor layer 602 includes, but is not limited to, a substrate, and the material of the substrate includes, but not limited to, an elemental semiconductor material (e.g., silicon (Si) or germanium (Ge), etc.), a III-V compound semiconductor material (e.g., gallium nitride (GaN), gallium arsenide (GaAs), or indium phosphide (InP), etc.), a II-VI compound semiconductor material (e.g., zinc sulfide (ZnS), cadmium sulfide (CdS), or cadmium telluride (CdTe), etc.), an organic semiconductor material, or other semiconductor material known in the art.

Both the analog-to-digital conversion circuit 108 and the interface circuit 110 may include one or more CMOS transistors, and the active region of the CMOS transistor may be located in the first semiconductor layer 602. As an example, referring to FIG. 8, the first semiconductor layer 602 may include a front surface and a back surface opposite to each other along the first direction, the active region of the CMOS transistor may be formed on the front surface of the first semiconductor layer 602, the pad dielectric layer 624 is formed on the back surface of the first semiconductor layer 602, and the pad 124 is located in the pad dielectric layer 624. The material of the pad dielectric layer 624 may include a dielectric material, such as one or more of silicon oxide, silicon nitride, silicon oxynitride, or a low-k dielectric.

In some examples, referring to FIG. 1A and FIG. 8, the first semiconductor structure 102 further includes a first dielectric structure 604, a first conductive structure 606, and a second conductive structure 608; the first dielectric structure 604 is located between the first semiconductor layer 602 and the second semiconductor structure 104, and both the first conductive structure 606 and the second conductive structure 608 are located in the first dielectric structure 604; where the pad 124 is coupled to the interface circuit 110 through the first conductive structure 606, and the peripheral circuit 114 is coupled to the analog-to-digital conversion circuit 108 through the second conductive structure 608.

In some examples, referring to FIG. 8, the first semiconductor structure 102 further includes a first connection structure 610, which extends through the first semiconductor layer 602 along the first direction; where two opposite ends of the first connection structure 610 along the first direction are connected to the pad 124 and the first conductive structure 606, respectively.

The first dielectric structure 604 covers various circuits formed on the front surface of the first semiconductor layer 602, and is configured to physically isolate various conductive structures formed on the front surface of the first semiconductor layer 602; for example, the first conductive structure 606 and the second conductive structure 608 are physically isolated by the first dielectric structure 604, and the first dielectric structure 604 may include one or more film layers.

As an example, referring to FIG. 8, the first dielectric structure 604 includes a first dielectric layer 612 and a first interconnection dielectric layer 614; the first dielectric layer 612 is located between the first semiconductor layer 602 and the first interconnection dielectric layer 614, and the first interconnection dielectric layer 614 is located between the first dielectric layer 612 and the second semiconductor structure 104. In an example, the first interconnection dielectric layer 614 is located between the first dielectric layer 612 and the third bonding layer 120. The material of the first dielectric layer 612 and other dielectric layers hereinafter may include a dielectric material, such as one or more of silicon oxide, silicon nitride, silicon oxynitride, or a low-k dielectric.

The first conductive structure 606 is configured to electrically lead out the interface circuit 110, for example, the interface circuit 110 may be coupled to the pad 124 through the first conductive structure 606 and the first connection structure 610. As an example, the first conductive structure 606 includes a first contact structure 616 and a first interconnection structure 618; the first contact structure 616 extends through the first dielectric layer 612 along the first direction, and the first interconnection structure 618 is located in the first interconnection dielectric layer 614; and two opposite ends of the first contact structure 616 along the first direction are connected to the first connection structure 610 and the first interconnection structure 618, respectively. The interface circuit 110 may be coupled to the pad 124 through the first interconnection structure 618, the first contact structure 616, and the first connection structure 610 sequentially.

The second conductive structure 608 is configured to electrically lead out the analog-to-digital conversion circuit 108, for example, the analog-to-digital conversion circuit 108 may be coupled to the peripheral circuit 114 through the second conductive structure 608 and other connection structures. As an example, the second conductive structure 608 includes a second contact structure 620 and a second interconnection structure 622; the second contact structure 620 extends through the first dielectric layer 612 along the first direction, and the second interconnection structure 622 is located in the first interconnection dielectric layer 614; where two opposite ends of the second contact structure 620 along the first direction are connected to the analog-to-digital conversion circuit 108 and the second interconnection structure 622, respectively. The analog-to-digital conversion circuit 108 may be coupled to the peripheral circuit 114 through the second contact structure 620 and the second interconnection structure 622 sequentially.

Both the first conductive structure 606 and the second conductive structure 608 may include one or more sub-conductive structures; for example, a plurality of contact structures are formed in the first dielectric layer 612, a plurality of interconnection structures are formed in the first interconnection dielectric layer 614, and the contact structures and the interconnection structures connected to each other constitute a conductive structure.

The contact structures (e.g., the first contact structure 616, the second contact structure 620, and other contact structures hereinafter) in the examples of the present disclosure may include contacts extending longitudinally. The contact structures may be formed in one or more dielectric layers. The material of the contact structure may include a conductive material including, but not limited to, at least one of a doped-semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.), and the like.

The interconnection structures (e.g., the first interconnection structure 618, the second interconnection structure 622, and the third interconnection structure to the ninth interconnection structure hereinafter) in the examples of the present disclosure may each include, for example, interconnection line (metal) extending laterally and interconnection contact (via) extending longitudinally. The interconnection structure may be formed in one or more interconnection dielectric layers. The material of the interconnection structure may include a conductive material including, but not limited to, at least one of a doped-semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.). The material of the interconnection dielectric layer may include a dielectric material including, but not limited to, silicon oxide, silicon nitride, silicon oxynitride, a low-k dielectric, or any combination thereof.

The connection structure (e.g., the first connection structure 610 and the second connection structure 688 to the seventh connection structure 678 hereinafter) in the examples of the present disclosure may include a through-silicon via (TSV) extending longitudinally. The connection structure may extend longitudinally through the silicon substrate. The material of the connection structure may include a conductive material, such as at least one of a doped-semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.), and the like.

It should be noted that, other dielectric layers are further disposed between the connection structure and the semiconductor layer through which the connection structure penetrates, so as to physically isolate the connection structure from the semiconductor layer through which the connection structure penetrates.

In some examples, referring to FIG. 8, a size of the first contact structure 616 close to the first semiconductor layer 602 in the second direction is smaller than or equal to a size of the first contact structure 616 away from the first semiconductor layer 602 in the second direction; and a size of the second contact structure 620 close to the first semiconductor layer 602 in the second direction is smaller than or equal to a size of the second contact structure 620 away from the first semiconductor layer 602 in the second direction.

As an example, the first contact structure 616 and the second contact structure 620 may be formed simultaneously, thereby simplifying the manufacturing process. The first contact structure 616 and the second contact structure 620 may be formed after the first dielectric layer 612 is formed on the front surface of the first semiconductor layer 602. The first dielectric layer 612 is etched along a direction toward the front surface of the first semiconductor layer 602 to form a plurality of contact holes penetrating through the first dielectric layer 612, and conductive materials are filled into the contact holes to form the first contact structure 616 and the second contact structure 620, respectively.

It should be noted that, due to the process limitation of etching, the size of the bottom of the contact hole formed generally in the second direction is smaller than or equal to the size of the top of the contact hole in the second direction, so that the size of the bottom of the contact structure formed by filling in the second direction is smaller than or equal to the size of the top of the contact structure in the second direction.

In the examples of the present disclosure, by disposing the first connection structure 610 extending through the first semiconductor layer 602 along the first direction, the electrical connection between the pad 124 disposed on the back surface of the first semiconductor layer 602 and the interface circuit 110 disposed on the front surface of the first semiconductor layer 602 may be achieved, so that the external interface of the semiconductor device does not need to be wound back from the first bonding interface. In practical applications, the silicon substrate may be etched from the back surface to form a through-silicon via extending through the silicon substrate, and a conductive material may be filled into the via to form a corresponding connection structure.

In some examples, referring to FIG. 8, a size of the first connection structure 610 close to the pad 124 in the second direction is greater than or equal to a size of the first connection structure 610 away from the pad 124 in the second direction.

It should be noted that, due to the process limitation of etching, the size of the top of the formed through-silicon via in the second direction is greater than or equal to the size of the bottom of the through-silicon via in the second direction, so that the size of the top of the connection structure formed by filling in the second direction is greater than or equal to the size of the bottom of the connection structure in the second direction.

In some examples, referring to FIG. 8, the second semiconductor structure 104 further includes a second semiconductor layer 626, a second dielectric structure 628, a third conductive structure 630, and a third connection structure 632; the second semiconductor layer 626 is located between the first semiconductor structure 102 and the second dielectric structure 628, the second dielectric structure 628 covers the step region of the memory array 112, the third conductive structure 630 is located in the second dielectric structure 628, and the third connection structure 632 extends through the second semiconductor layer 626 along the first direction; where the peripheral circuit 114 is coupled to the analog-to-digital conversion circuit 108 through the third conductive structure 630 and the third connection structure 632.

In some examples, referring to FIG. 7 and FIG. 8, the first semiconductor structure 102 further includes a controller 504; a portion of the controller 504 is located in the first semiconductor layer 602; the second semiconductor structure 104 further includes a fourth conductive structure 634 and a fourth connection structure 636; the fourth conductive structure 634 is located in the second dielectric structure 628, and the fourth connection structure 636 extends through the second semiconductor layer 626 along the first direction; where the controller 504 is coupled to the peripheral circuit 114 through the fourth connection structure 636 and the fourth conductive structure 634. Here, the controller 504 may include one or more CMOS transistors, and the active region of the CMOS transistor may be located in the first semiconductor layer 602.

In some examples, referring to FIG. 7 and FIG. 8, the second semiconductor structure 104 further includes a fifth conductive structure 638 and a fifth connection structure 640; the fifth conductive structure 638 is located in the second dielectric structure 628, and the fifth connection structure 640 extends through the second semiconductor layer 626 along the first direction; where the controller 504 is further coupled to the peripheral circuit 114 through the fifth connection structure 640 and the fifth conductive structure 638; and the fifth connection structure 640 and the fourth connection structure 636 are configured to transmit different control signals, respectively.

The second semiconductor layer 626 includes, but is not limited to, a substrate, and the material of the substrate may include one of the above-described materials in the related description, and the details are not repeated here. The second semiconductor layer 626 may include a front surface and a back surface opposite to each other along the first direction, the memory array 112 may be formed on the front surface of the second semiconductor layer 626, and for the structure of the memory array 112, referring to the related description of FIG. 2 and FIG. 3.

The second dielectric structure 628 covers the step region of the memory array 112 formed on the front surface of the second semiconductor layer 626, and the second dielectric structure 628 is configured to physically isolate various conductive structures formed on the front surface of the second semiconductor layer 626, for example, the third conductive structure 630, the fourth conductive structure 634, and the fifth conductive structure 638 are physically isolated from each other by the first dielectric structure 604, and the second dielectric structure 628 may include one or more film layers.

As an example, referring to FIG. 8, the second dielectric structure 628 includes a second dielectric layer 642 and a second interconnection dielectric layer 644; the second dielectric layer 642 is located between the second semiconductor layer 626 and the second interconnection dielectric layer 644, and the second interconnection dielectric layer 644 is located between the second dielectric layer 642 and the third semiconductor structure 106. In an example, the second interconnection dielectric layer 644 is located between the second dielectric layer 642 and the second bonding layer 118.

The third connection structure 632 and the third conductive structure 630 are collectively configured to realize an electrical connection between the peripheral circuit 114 and the analog-to-digital conversion circuit 108. As an example, the third conductive structure 630 includes a contact structure (e.g., a tenth contact structure) extending through the second dielectric layer 642 along the first direction and a third interconnection structure located in the second interconnection dielectric layer 644. The analog-to-digital conversion circuit 108 may be coupled to the peripheral circuit 114 through the second conductive structure 608, the bonding contact across the first bonding interface, the third connection structure 632, the third conductive structure 630, and the bonding contact across the second bonding interface, sequentially.

The fourth connection structure 636 and the fourth conductive structure 634 are collectively configured to realize an electrical connection between the peripheral circuit 114 and the controller 504. As an example, the fourth conductive structure 634 includes a fourth contact structure extending through the second dielectric layer 642 along the first direction and a fourth interconnection structure located in the second interconnection dielectric layer 644. The controller 504 may be coupled to the peripheral circuit 114 through other conductive structures (not shown) on the front surface of the first semiconductor layer 602, the bonding contact across the first bonding interface, the fourth connection structure 636, the fourth conductive structure 634, and the bonding contact across the second bonding interface sequentially. Here, the first line via the fourth connection structure 636 and the fourth conductive structure 634 is configured to transmit the first control signal.

The fifth connection structure 640 and the fifth conductive structure 638 are collectively configured to realize an electrical connection between the peripheral circuit 114 and the controller 504. As an example, the fifth conductive structure 638 includes a fifth contact structure extending through the second dielectric layer 642 along the first direction and a fifth interconnection structure located in the second interconnection dielectric layer 644. The controller 504 may be coupled to the peripheral circuit 114 through other conductive structures (not shown) on the front surface of the first semiconductor layer 602, the bonding contact across the first bonding interface, the fifth connection structure 640, the fifth conductive structure 638, and the bonding contact across the second bonding interface in sequence. Here, the second line via the fifth connection structure 640 and the fifth conductive structure 638 is configured to transmit the second control signal which is different from the first control signal.

Taking the ONFI interface as an example, the controller 504 and memory may perform signal interactions based on the ONFI protocol, which defines a series of commands and data transmission formats. However, with the iteration of chips and the continuous development of semiconductor technology, standard ONFI interfaces will face new challenges, such as difficulty in meeting the transmission requirements of customized other control signals. Based on this, in the examples of the present disclosure, by disposing the first line including the fourth connection structure 636 and the fourth conductive structure 634 and the second line including the fifth connection structure 640 and the fifth conductive structure 638, the first line and the second line may be configured to transmit different types of control signals, respectively, for example, the first line is configured to transmit a command specified by the ONFI protocol, and the second line is configured to transmit customized other commands, so that the standard interface can be extended to meet the signal interaction requirement under different scenarios.

In some examples, referring to FIG. 8, a size of the tenth contact structure close to the second semiconductor layer 626 in the second direction is smaller than or equal to a size of the tenth contact structure away from the second semiconductor layer 626 in the second direction; a size of the fourth contact structure close to the second semiconductor layer 626 in the second direction is smaller than or equal to a size of the fourth contact structure away from the second semiconductor layer 626 in the second direction; and a size of the fifth contact structure close to the second semiconductor layer 626 in the second direction is smaller than or equal to a size of the fifth contact structure away from the second semiconductor layer 626 in the second direction.

As an example, the tenth contact structure, the fourth contact structure, and the fifth contact structure may be formed simultaneously, thereby simplifying the manufacturing process. The tenth contact structure, the fourth contact structure and the fifth contact structure may be formed after the second dielectric layer 642 is formed on the front surface of the second semiconductor layer 626. The second dielectric layer 642 is etched along a direction toward the front surface of the second semiconductor layer 626 to form a plurality of contact holes penetrating through the second dielectric layer 642, and the contact holes are filled with the conductive material to form the tenth contact structure, the fourth contact structure and the fifth contact structure, respectively.

In the examples of the present disclosure, by disposing the third connection structure 632, the fourth connection structure 636 and the fifth connection structure 640 extending through the second semiconductor layer 626 along the first direction, the electrical connections between the analog-to-digital conversion circuit 108 and the controller 504 disposed on the back surface of the second semiconductor layer 626 and the peripheral circuits 114 disposed on the front surface of the second semiconductor layer 626 can be realized.

In some examples, the size of the third connection structure 632 close to the second dielectric structure 628 in the second direction is smaller than or equal to the size of the third connection structure 632 away from the second dielectric structure 628 in the second direction; the size of the fourth connection structure 636 close to the second dielectric structure 628 in the second direction is smaller than or equal to the size of the fourth connection structure 636 away from the second dielectric structure 628 in the second direction; and the size of the fifth connection structure 640 close to the second dielectric structure 628 in the second direction is smaller than or equal to the size of the fifth connection structure 640 away from the second dielectric structure 628 in the second direction.

As an example, the third connection structure 632, the fourth connection structure 636 and the fifth connection structure 640 may be formed simultaneously, thereby simplifying the manufacturing process. The third connection structure 632, the fourth connection structure 636, and the fifth connection structure 640 may be formed after the second bonding layer 118 is bonded to the fourth bonding layer 122. The second semiconductor layer 626 is etched along a direction toward the back surface of the second semiconductor layer 626 to form a plurality of through-silicon vias penetrating through the second semiconductor layer 626, and the through-silicon vias are filled with a conductive material to form the third connection structure 632, the fourth connection structure 636, and the fifth connection structure 640, respectively.

In some examples, referring to FIG. 8, the second semiconductor structure 104 further includes a bit line 646 coupled to the memory array 112, and the bit line 646 is located between the memory array 112 and the third semiconductor structure 106; the third semiconductor structure 106 further includes a third semiconductor layer 648, a third dielectric structure 650, and an eighth conductive structure 652; the third dielectric structure 650 is located between the second semiconductor structure 104 and the third semiconductor layer 648, and the eighth conductive structure 652 is located in the third dielectric structure 650; where the peripheral circuit 114 is coupled to the bit line 646 through the eighth conductive structure 652. For the bit line 646, referring to the related description of the bit line 222 shown in FIG. 2, and the bit lines BL0 to BL2 shown in FIG. 5.

The third semiconductor layer 648 includes, but is not limited to, a substrate, and for the material of the substrate, referring to the above related description, and details are not described herein again. The third semiconductor layer 648 may include a front surface and a back surface opposite to each other along the first direction, the peripheral circuit 114 may be formed on the front surface of the third semiconductor layer 648, and for the peripheral circuit 114, referring to the related description of FIG. 2 and FIG. 4.

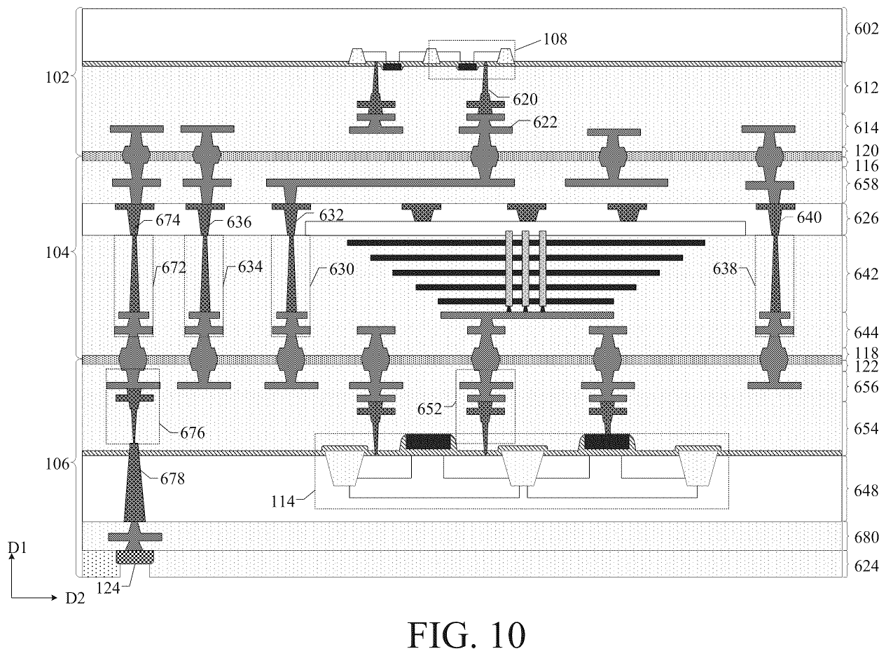

The third dielectric structure 650 covers the peripheral circuit 114 formed on the front surface of the third semiconductor layer 648, and the third dielectric structure 650 is configured to physically isolate various conductive structures formed on the front surface of the third semiconductor layer 648; for example, the eighth conductive structure 652 and the seventh conductive structure 676 in FIG. 10 are physically isolated from each other by the third dielectric structure 650, and the third dielectric structure 650 may include one or more film layers.

As an example, referring to FIG. 8, the third dielectric structure 650 includes a third dielectric layer 654 and a third interconnection dielectric layer 656; the third dielectric layer 654 is located between the third semiconductor layer 648 and the third interconnection dielectric layer 656, and the third interconnection dielectric layer 656 is located between the third dielectric layer 654 and the second semiconductor structure 104. In an example, the third interconnection dielectric layer 656 is located between the third dielectric layer 654 and the fourth bonding layer 122.

The eighth conductive structure 652 is configured to realize an electrical connection between the bit line 646 and the peripheral circuit 114. As an example, the eighth conductive structure 652 includes an eighth contact structure and an eighth interconnection structure; the eighth contact structure extends through the third dielectric layer 654 along the first direction, and the eighth interconnection structure is located in the third interconnection dielectric layer 656; where two opposite ends of the eighth contact structure along the first direction are connected to the peripheral circuit 114 and the eighth interconnection structure, respectively. The bit line 646 may be coupled to the peripheral circuit 114 sequentially through the bonding contact across the second bonding interface and the eighth conductive structure 652.

In some examples, referring to FIG. 8, a size of the eighth contact structure close to the third semiconductor layer 648 in the second direction is smaller than or equal to a size of the eighth contact structure away from the third semiconductor layer 648 in the second direction.

In some examples, referring to FIGS. 1A and 8, the first bonding layer 116 includes a first bonding contact 660 and a first bonding dielectric layer that isolates the first bonding contact 660, the second bonding layer 118 includes a second bonding contact 664 and a second bonding dielectric layer that isolates the second bonding contact 664, the third bonding layer 120 includes a third bonding contact 662 and a third bonding dielectric layer that isolates the third bonding contact 662, the fourth bonding layer 122 includes a fourth bonding contact 666 and a fourth bonding dielectric layer that isolates the fourth bonding contact 666; where the first bonding contact 660 and the third bonding contact 662 are bonded, the first bonding dielectric layer and the third bonding dielectric layer are bonded; the second bonding contact 664 and the fourth bonding contact 666 are bonded, and the second bonding dielectric layer and the fourth bonding dielectric layer are bonded.

In some examples, the bonding contact may include a conductive material including, but not limited to, one or more of tungsten, cobalt, copper, aluminum, or polysilicon. As an example, the bonding contact of the bonding layer includes copper, the remaining region of the bonding layer may be formed of a dielectric including, but not limited to, one or more of silicon oxide, silicon nitride, silicon oxynitride, or a low-k dielectric. The bonding contact and the surrounding dielectric in the bonding layer may be used for hybrid bonding, and metal-to-metal bonding and dielectric-to-dielectric bonding may be obtained simultaneously.

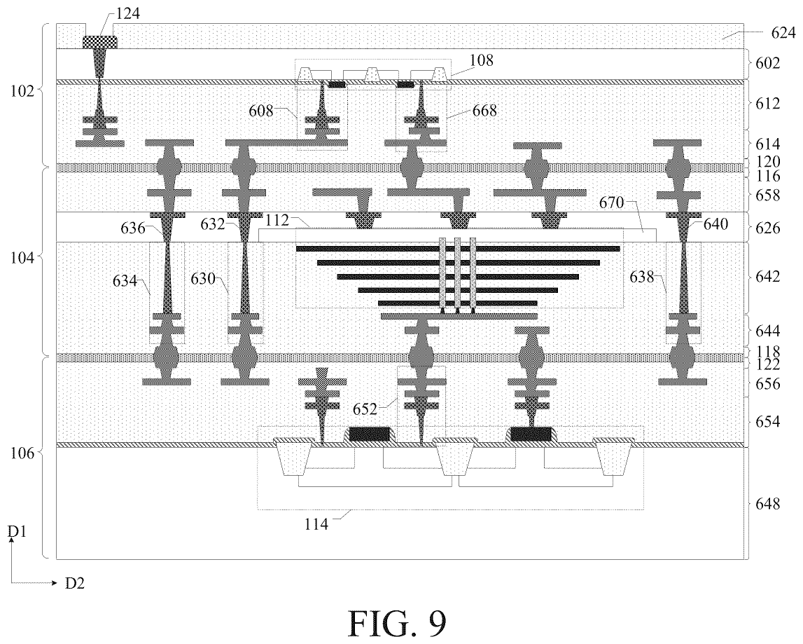

FIG. 9 is a schematic cross-sectional view of a semiconductor device provided by a second example of the present disclosure. Referring to FIG. 1A and FIG. 9, the semiconductor device includes a first semiconductor structure 102, a second semiconductor structure 104, and a third semiconductor structure 106 sequentially stacked along a first direction; the first semiconductor structure 102 includes an analog-to-digital conversion circuit 108 and an interface circuit 110, the second semiconductor structure 104 includes a memory array 112, the third semiconductor structure 106 includes a peripheral circuit 114 coupled to the memory array 112 and the analog-to-digital conversion circuit 108, respectively; the analog-to-digital conversion circuit 108 is configured to receive the analog information obtained by performing an operation by the memory array 112; where the first semiconductor structure 102 further includes a pad 124 coupled to the interface circuit 110 and located on one side of two opposite sides of the analog-to-digital conversion circuit 108 along the first direction away from the second semiconductor structure 104.

In some examples, referring to FIG. 1A, FIG. 8, and FIG. 9, the first semiconductor structure 102 further includes a first dielectric structure 604 and a ninth conductive structure 668; the first dielectric structure 604 is located between the pad 124 and the second semiconductor structure 104, and the ninth conductive structure 668 is located in the first dielectric structure 604; the second semiconductor structure 104 further includes a source line 670 coupled to the memory array 112 and located between the memory array 112 and the first semiconductor structure 102; where the ninth conductive structure 668 is coupled to the source line 670 and the analog-to-digital conversion circuit 108, respectively, and the analog operation result is transmitted to the analog-to-digital conversion circuit 108 through the source line 670 and the ninth conductive structure 668. It may be understood that, in the example shown in FIG. 9, the source line 670 may be used as the output terminal of the analog information.

The ninth conductive structure 668 is configured to realize a connection between the analog-to-digital conversion circuit 108 and the source line 670. As an example, the ninth conductive structure 668 includes a ninth contact structure and a ninth interconnection structure; the ninth contact structure extends through the first dielectric layer 612 along the first direction, and the ninth interconnection structure is located in the first interconnection dielectric layer 614; where two opposite ends of the ninth contact structure along the first direction are connected to the analog-to-digital conversion circuit 108 and the ninth interconnection structure, respectively. The analog-to-digital conversion circuit 108 may be coupled to the source line 670 through the ninth conductive structure 668, the bonding contact across the first bonding interface, and other connection structures extending through the second semiconductor layer 626 sequentially.

In some examples, a size of the ninth contact structure close to the first semiconductor layer 602 in the second direction is smaller than or equal to a size of the ninth contact structure away from the first semiconductor layer 602 in the second direction. The ninth contact structure may be formed simultaneously with the first contact structure 616 and the second contact structure 620 in FIG. 8, thereby simplifying the manufacturing process.

FIG. 10 is a schematic cross-sectional view of a semiconductor device provided by a third example of the present disclosure. Referring to FIG. 1B and FIG. 10, the semiconductor device includes a first semiconductor structure 102, a second semiconductor structure 104, and a third semiconductor structure 106 sequentially stacked along a first direction; the first semiconductor structure 102 includes an analog-to-digital conversion circuit 108 and an interface circuit 110, the second semiconductor structure 104 includes a memory array 112, the third semiconductor structure 106 includes a peripheral circuit 114, and the peripheral circuit 114 is coupled to the memory array 112 and the analog-to-digital conversion circuit 108, respectively; the analog-to-digital conversion circuit 108 is configured to receive the analog information obtained by performing an operation by the memory array 112; where the third semiconductor structure 106 further includes a pad 124 coupled to the interface circuit 110 and located on one side of two opposite sides of the peripheral circuit 114 along the first direction away from the second semiconductor structure 104.

In some examples, the second semiconductor structure 104 further includes a sixth conductive structure 672 and a sixth connection structure 674; the sixth conductive structure 672 is located in the second dielectric structure 628, and the sixth connection structure 674 extends through the second semiconductor layer 626 along the first direction; the third semiconductor structure 106 further includes a third semiconductor layer 648, a third dielectric structure 650, a seventh conductive structure 676, and a seventh connection structure 678; the third semiconductor layer 648 is located between the pad 124 and the third dielectric structure 650, and a portion of the peripheral circuit 114 is located in the third semiconductor layer 648; the third dielectric structure 650 is located between the third semiconductor layer 648 and the second semiconductor structure 104, and the seventh conductive structure 676 is located in the third dielectric structure 650; the seventh connection structure 678 extends through the third semiconductor layer 648 along the first direction; where the pad 124 is coupled to the interface circuit 110 through the seventh connection structure 678, the seventh conductive structure 676, the sixth conductive structure 672, and the sixth connection structure 674.

In the example of the present disclosure, the pad 124 may be formed on the back surface of the third semiconductor layer 648, and the sixth connection structure 674, the sixth conductive structure 672, the seventh conductive structure 676, and the seventh connection structure 678 are collectively configured to realize the electrical connection between the interface circuit 110 and the pad 124. For the second semiconductor layer 626, the second dielectric structure 628, the third semiconductor layer 648, and the third dielectric structure 650, are described with reference to FIG. 8, the details of which are not repeated here.

As an example, the sixth conductive structure 672 includes a sixth contact structure and a sixth interconnection structure; the sixth contact structure extends through the second dielectric layer 642 along the first direction, and the sixth interconnection structure is located in the second interconnection dielectric layer 644; where two opposite ends of the sixth contact structure along the first direction are connected to the sixth connection structure 674 and the sixth interconnection structure, respectively. Here, the sixth contact structure may be formed simultaneously with the tenth contact structure, the fourth contact structure, and the fifth contact structure, thereby simplifying the manufacturing process.

As an example, the seventh conductive structure 676 includes a seventh contact structure and a seventh interconnection structure; the seventh contact structure extends through the third dielectric layer 654 along the first direction, and the seventh interconnection structure is located in the third interconnection dielectric layer 656; where two opposite ends of the seventh contact structure along the first direction are connected to the seventh connection structure 678 and the seventh interconnection structure, respectively. Here, the seventh contact structure may be formed simultaneously with the eighth contact structure, thereby simplifying the manufacturing process.

As an example, the third semiconductor layer 648 may be etched along a direction toward the back surface of the third semiconductor layer 648 to form a through-silicon via penetrating through the third semiconductor layer 648, and a conductive material may be filled into the through-silicon via to form the seventh connection structure 678.

It may be understood that, in the example shown in FIG. 10, the interface circuit 110 may be coupled to the pad 124 through the first conductive structure 606, the bonding contact across the first bonding interface, the sixth connection structure 674, the sixth conductive structure 672, the bonding contact across the second bonding interface, the seventh conductive structure 676, and the seventh connection structure 678 shown in FIG. 8, sequentially. Of course, in other examples, a fourth dielectric layer 680 and an interconnection structure located in the fourth dielectric layer 680 may also be formed between the third semiconductor layer 648 and the pad dielectric layer 624, and the interconnection structure is coupled to the seventh connection structure 678 and the pad 124, respectively.

In the examples of the present disclosure, the interface circuit 110 may be led out to the pad 124 disposed on the back surface of the third semiconductor layer 648 by disposing corresponding connection structures, contact structures and the like in the second semiconductor structure 104 and the third semiconductor structure 106. Since the process nodes corresponding to the second semiconductor structure 104 and the third semiconductor structure 106 are larger, the process of forming the connection structures and the contact structures has a lower requirement for the lithographic equipment, for example, lower cost lithography equipment may be used, thereby saving cost. In addition, a high-voltage device (for example, a high-voltage transistor) is usually disposed in the peripheral circuit 114, thereby facilitating a high-voltage design by disposing the pad 124 on the back surface of the third semiconductor layer 648.

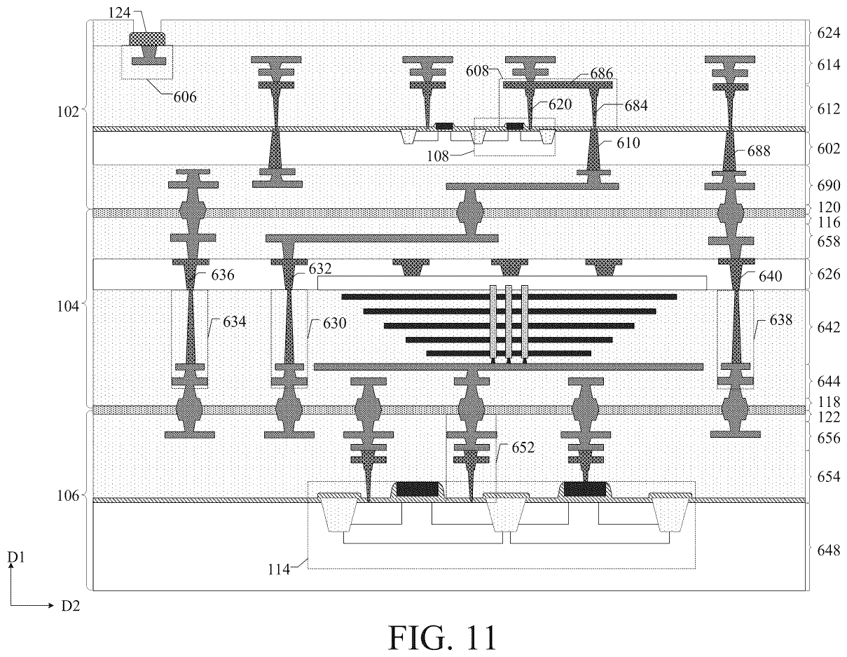

FIG. 11 is a schematic cross-sectional view of a semiconductor device provided by a fourth example of the present disclosure. Referring to FIG. 1A and FIG. 11, the semiconductor device includes a first semiconductor structure 102, a second semiconductor structure 104, and a third semiconductor structure 106 sequentially stacked along a first direction; the first semiconductor structure 102 includes an analog-to-digital conversion circuit 108 and an interface circuit 110, the second semiconductor structure 104 includes a memory array 112, the third semiconductor structure 106 includes a peripheral circuit 114 coupled to the memory array 112 and the analog-to-digital conversion circuit 108, respectively; the analog-to-digital conversion circuit 108 is configured to receive the analog information obtained by performing an operation by the memory array 112; where the first semiconductor structure 102 further includes a pad 124 coupled to the interface circuit 110 and located on one side of two opposite sides of the analog-to-digital conversion circuit 108 along the first direction away from the second semiconductor structure 104.

In some examples, referring to FIG. 1A and FIG. 11, the first semiconductor structure 102 further includes a first dielectric structure 604, a first conductive structure 606, and a second conductive structure 608; the first dielectric structure 604 is located between the pad 124 and the first semiconductor layer 602, and both the first conductive structure 606 and the second conductive structure 608 are located in the first dielectric structure 604; where the pad 124 is coupled to the interface circuit 110 through the first conductive structure 606, and the peripheral circuit 114 is coupled to the analog-to-digital conversion circuit 108 through the second conductive structure 608.

In some examples, referring to FIG. 11, the first semiconductor structure 102 further includes a first connection structure 610; the first connection structure 610 extends through the first semiconductor layer 602 along the first direction; where the peripheral circuit 114 is coupled to the second conductive structure 608 through the first connection structure 610.

As an example, referring to FIG. 11, the first semiconductor layer 602 may include a front surface and a back surface opposite to each other along the first direction, the active region of the CMOS transistor may be formed on the front surface of the first semiconductor layer 602, the pad dielectric layer 624 is formed on the front surface of the first semiconductor layer 602, and the pad 124 is located in the pad dielectric layer 624.

The first dielectric structure 604 covers various circuits formed on the front surface of the first semiconductor layer 602, the first dielectric structure 604 is configured to physically isolate various conductive structures formed on the front surface of the first semiconductor layer 602, and the first dielectric structure 604 may include one or more film layers. As an example, referring to FIG. 11, the first dielectric structure 604 includes a first dielectric layer 612 and a first interconnection dielectric layer 614; the first dielectric layer 612 is located between the first semiconductor layer 602 and the first interconnection dielectric layer 614, and the first interconnection dielectric layer 614 is located between the first dielectric layer 612 and the pad 124. In an example, the first interconnection dielectric layer 614 is located between the first dielectric layer 612 and the pad dielectric layer 624.

The first conductive structure 606 is configured to electrically lead out the interface circuit 110, for example, the interface circuit 110 may be coupled to the pad 124 through the first conductive structure 606. As an example, the first conductive structure 606 includes a first contact structure and a first interconnection structure; the first contact structure extends through the first dielectric layer 612 along the first direction, and the first interconnection structure is located in the first interconnection dielectric layer 614; where the pad 124 is connected to the first interconnection structure, and two opposite ends of the first contact structure along the first direction are connected to the first interconnection structure and the interface circuit 110, respectively.

The second conductive structure 608 is configured to electrically lead out the analog-to-digital conversion circuit 108, for example, the analog-to-digital conversion circuit 108 may be coupled to the peripheral circuit 114 through the second conductive structure 608. As an example, the second conductive structure 608 includes a second contact structure 620, a third contact structure 684, and a conductive line 686; both the second contact structure 620 and the third contact structure 684 extend through the first dielectric layer 612 along the first direction, and the conductive line 686 is located in the first interconnection dielectric layer 614; where two opposite ends of the second contact structure 620 along the first direction are connected to the analog-to-digital conversion circuit 108 and the conductive line 686, respectively, and two opposite ends of the third contact structure 684 along the first direction are connected to the first connection structure 610 and the conductive line 686, respectively. The analog-to-digital conversion circuit 108 may be coupled to the peripheral circuit 114 through the second contact structure 620, the conductive line 686, the third contact structure 684, the first connection structure 610, the bonding contact across the first bonding interface, the third connection structure 632, the third conductive structure 630, and the bonding contact across the second bonding interface sequentially.

In the examples of the present disclosure, by disposing the analog-to-digital conversion circuit 108 and the interface circuit 110 on the front surface of the first semiconductor layer 602, and disposing the pad 124 on the front surface of the first semiconductor layer 602 (e.g., by leading out the pad 124 from the front surface of the first semiconductor layer 602), the external interface of the semiconductor device does not need to be wound back from the first bonding interface. In this way, the winding inside the first semiconductor structure 102 can be reduced, the signal transmission distance can be shortened, and the signal delay can be reduced.

In some examples, referring to FIG. 7 and FIG. 11, the first semiconductor structure 102 further includes a second connection structure 688 and a controller 504; the second connection structure 688 extends through the first semiconductor layer 602 along the first direction, and a portion of the controller 504 is located in the first semiconductor layer 602; where the peripheral circuit 114 is coupled to the controller 504 through the second connection structure 688. As an example, referring to FIG. 11, the controller 504 may be coupled to the peripheral circuit 114 through other conductive structures (not shown) on the front surface of the first semiconductor layer 602, the second connection structure 688, the bonding contact across the first bonding interface, the fifth connection structure 640, the fifth conductive structure 638, and the bonding contact across the second bonding interface sequentially.

As an example, the first connection structure 610 and the second connection structure 688 may be formed simultaneously, thereby simplifying the manufacturing process. The first connection structure 610 and the second connection structure 688 may be bonded to the carrier substrate after the front surface process of the first semiconductor layer 602 is completed, and inverted so that the back surface of the first semiconductor layer 602 faces upward, the first semiconductor layer 602 is etched along a direction towards the back surface of the first semiconductor layer 602 to form a plurality of through-silicon vias penetrating through the first semiconductor layer 602, and conductive materials are filled into the through-silicon vias to form the first connection structure 610 and the second connection structure 688, respectively.

In some examples, referring to FIG. 8, FIG. 9, FIG. 10, and FIG. 11, the second semiconductor structure 104 further includes a fourth interconnection dielectric layer 658 located between the second semiconductor layer 626 and the first bonding layer 116. After the plurality of connection structures (e.g., the third connection structure 632, the fourth connection structure 636, and the fifth connection structure 640) are formed in the second semiconductor layer 626, the fourth interconnection dielectric layer 658 may be formed on the back surface of the second semiconductor layer 626 and a plurality of interconnection structures may be formed in the fourth interconnection dielectric layer 658, and the interconnection structure in the fourth interconnection dielectric layer 658 may be configured to realize the electrical connection between the connection structure in the second semiconductor layer 626 and the first bonding contact 660.

In some examples, referring to FIG. 8 and FIG. 11, the first semiconductor structure 102 further includes a fifth interconnection dielectric layer 690 located between the first semiconductor layer 602 and the third bonding layer 120. After the plurality of connection structures (for example, the first connection structure 610 and the second connection structure 688) are formed in the first semiconductor layer 602, the fifth interconnection dielectric layer 690 may be formed on the back surface of the first semiconductor layer 602 and a plurality of interconnection structures may be formed in the fifth interconnection dielectric layer 690, and the interconnection structures in the fifth interconnection dielectric layer 690 are configured to realize the electrical connection between the connection structures in the first semiconductor layer 602 and the third bonding contact 662.

Based on a concept similar to that of the above examples, an example of the present disclosure further provides another semiconductor device.

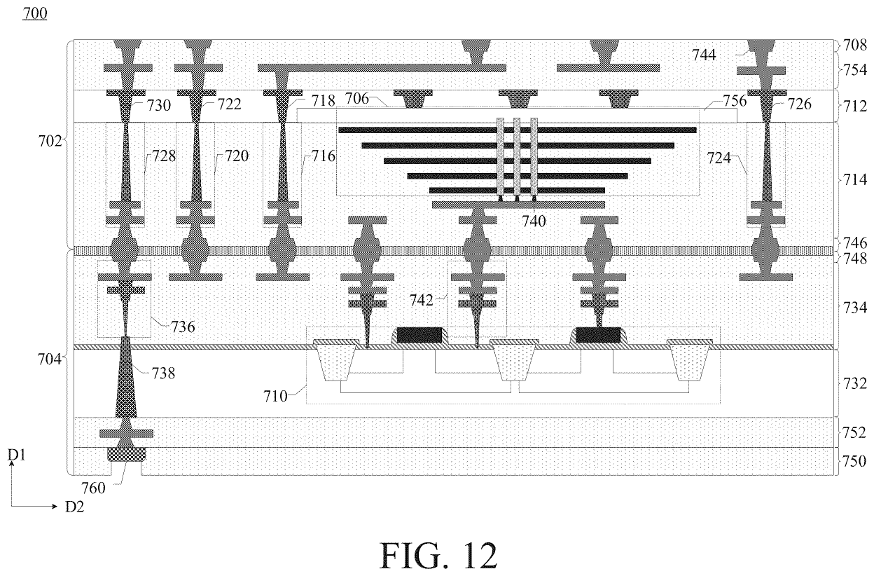

FIG. 12 is another schematic cross-sectional view of a semiconductor device provided by an example of the present disclosure. Referring to FIG. 12, the semiconductor device 700 includes a first semiconductor structure 702 and a second semiconductor structure 704 sequentially stacked in a first direction; the first semiconductor structure 702 includes a memory array 706 and a bonding layer 708; the bonding layer 708 is located on one side of two opposite sides of the memory array 706 along the first direction away from the second semiconductor structure 704; the second semiconductor structure 704 includes a peripheral circuit 710 and a pad 760; the peripheral circuit 710 is coupled to the memory array 706; where the pad 760 is located on one side of two opposite sides of the peripheral circuit 710 along the first direction away from the first semiconductor structure 702; and the pad 760 is configured to output an operation result obtained by performing an operation by the memory array 706.

The semiconductor device 700 includes, but is not limited to, 3D NAND, and the memory array 706 includes a three-dimensional NAND type memory array. The bonding layer 708 is configured to bond with other semiconductor structures (for example, a logic chip including an analog-to-digital conversion circuit, a front-end interface, and a controller), thereby realizing a bonding connection between the 3D NAND and the logic chip. By disposing a pad 760 on one side of two opposite sides of the peripheral circuit 710 along the first direction away from the first semiconductor structure 702, an operation result obtained by performing an operation by the memory array 706 may be output through the pad 760, thereby reserving an external interface for a device formed by bonding the 3D NAND with other logic chips.

In some examples, referring to FIG. 12, the first semiconductor structure 702 further includes a first semiconductor layer 712, a first dielectric structure 714, a first conductive structure 716, and a first connection structure 718; the first semiconductor layer 712 is located between the bonding layer 708 and the first dielectric structure 714, the first dielectric structure 714 covers the step region of the memory array 706, the first conductive structure 716 is located in the first dielectric structure 714, and the first connection structure 718 extends through the first semiconductor layer 712 along the first direction; where the peripheral circuit 710 is coupled to the first connection structure 718 through the first conductive structure 716, and the first connection structure 718 is configured to transmit the analog information obtained by performing an operation by the memory array 706.

The first semiconductor layer 712 includes, but is not limited to, a substrate, and for the material of the substrate, reference may be made the above related description, the details of which will not be repeated here. The first semiconductor layer 712 may include a front surface and a back surface opposite to each other along the first direction, the memory array 706 may be formed on the front surface of the first semiconductor layer 712, and for the structure of the memory array 706, referring to the related description of FIG. 2 and FIG. 3.

The first dielectric structure 714 covers the step region of the memory array 706 formed on the front surface of the first semiconductor layer 712, and the first dielectric structure 714 is configured to physically isolate various conductive structures formed on the front surface of the first semiconductor layer 712; for example, the first conductive structure 716, the second conductive structure 720, the third conductive structure 724, and the fourth conductive structure 728 in the following are physically isolated from each other by the first dielectric structure 714, and the first dielectric structure 714 may include one or more film layers.

The first connection structure 718 is configured to transmit the analog information obtained by performing an operation by the memory array 706; for example, the analog information obtained by performing an operation by the memory array 706 may be transmitted to the analog-to-digital conversion circuit in the logic chip through the first conductive structure 716, the first connection structure 718, and the bonding contact 744 in the bonding layer 708.

In some examples, the first semiconductor structure 702 further includes a second conductive structure 720 and a second connection structure 722; the second conductive structure 720 is located in the first dielectric structure 714, and the second connection structure 722 extends through the first semiconductor layer 712 along the first direction; where the peripheral circuit 710 is coupled to the second connection structure 722 through the second conductive structure 720, and the second connection structure 722 is configured to transmit the first control signal.

The second connection structure 722 is configured to transmit a first control signal, for example, a first command sent by a controller in the logic chip may be transmitted to the peripheral circuit 710 through the bonding contact 744 in the bonding layer 708, the second connection structure 722, the second conductive structure 720, and the bonding contact across the bonding interface of the first semiconductor structure 702 and the second semiconductor structure 704. Here, the first control signal includes a first command.

In some examples, the first semiconductor structure 702 further includes a third conductive structure 724 and a third connection structure 726; the third conductive structure 724 is located in the first dielectric structure 714, and the third connection structure 726 extends through the first semiconductor layer 712 along the first direction; where the peripheral circuit 710 is coupled to the third connection structure 726 through the third conductive structure 724, and the third connection structure 726 is configured to transmit a second control signal different from the first control signal.

The third connection structure 726 is configured to transmit a second control signal, for example, the second command sent by the controller in the logic chip may be transmitted to the peripheral circuit 710 through the bonding contact 744 in the bonding layer 708, the third connection structure 726, the third conductive structure 724, and the bonding contact across the bonding interface of the first semiconductor structure 702 and the second semiconductor structure 704. Here, the second control signal includes a second command different from the first command.

In the example of the present disclosure, by providing the first line including the second connection structure 722 and the second conductive structure 720 and the second line including the third connection structure 726 and the third conductive structure 724, the first line and the second line may be configured to transmit different types of commands, respectively; for example, the first line is configured to transmit a command specified by the ONFI protocol, and the second line is configured to transmit other customized command, so that the standard interface may be extended, and the 3D NAND may meet the signal interaction requirement under different scenarios.

In some examples, the first semiconductor structure 702 further includes a fourth conductive structure 728 and a fourth connection structure 730; the fourth conductive structure 728 is located in the first dielectric structure 714, and the fourth connection structure 730 extends through the first semiconductor layer 712 along the first direction; the second semiconductor structure 704 further includes a second semiconductor layer 732, a second dielectric structure 734, a fifth conductive structure 736, and a fifth connection structure 738; the second semiconductor layer 732 is located between the pad 760 and the second dielectric structure 734, and a portion of the peripheral circuit 710 is located in the second semiconductor layer 732; the second dielectric structure 734 is located between the second semiconductor layer 732 and the first semiconductor structure 702, and the fifth conductive structure 736 is located in the second dielectric structure 734; the fifth connection structure 738 extends through the second semiconductor layer 732 along the first direction; where the pad 760 is connected to the fourth connection structure 730 through the fifth connection structure 738, the fifth conductive structure 736, and the fourth conductive structure 728.

The second semiconductor layer 732 includes, but is not limited to, a substrate, and for the material of the substrate, reference may be made to the above related description, the details of which will not be repeated here. The second semiconductor layer 732 may include a front surface and a back surface opposite to each other along the first direction, the peripheral circuit 710 may be formed on the front surface of the second semiconductor layer 732, and for the peripheral circuit 710, reference is made to the related description of FIG. 2 and FIG. 4.

The second dielectric structure 734 covers the peripheral circuit 710 formed on the front surface of the second semiconductor layer 732, and the second dielectric structure 734 is configured to physically isolate various conductive structures formed on the front surface of the second semiconductor layer 732,; for example, the fifth conductive structure 736 and the sixth conductive structure 742 in the following are physically isolated from each other by the second dielectric structure 734, and the second dielectric structure 734 may include one or more film layers.

The pad dielectric layer 750 is located on the back surface of the second semiconductor layer 732, the pad 760 is located in the pad dielectric layer 750, and the pad 760 may be coupled to the interface circuit in the logic chip through the fifth connection structure 738, the fifth conductive structure 736, the fourth conductive structure 728, and the fourth connection structure 730. Of course, in other examples, a dielectric layer 752 and an interconnection structure located in the dielectric layer 752 may also be formed between the second semiconductor layer 732 and the pad dielectric layer 750, and the interconnection structure is coupled to the fifth connection structure 738 and the pad 760, respectively.

In the examples of the present disclosure, by disposing corresponding connection structures, conductive structures, and the like in the first semiconductor structure 702 and the second semiconductor structure 704, the pad 760 located on the back surface of the second semiconductor layer 732 may be coupled to an interface circuit in the logic chip through corresponding connection structures and conductive structures. In addition, a high-voltage device (for example, a high-voltage transistor) is usually disposed in the peripheral circuit 710, thereby facilitating a high-voltage design by disposing the pad 760 on the back surface of the second semiconductor layer 732.

In some examples, the first semiconductor structure 702 further includes a bit line 740 coupled to the memory array 706, the bit line 740 is located between the memory array 706 and the second semiconductor structure 704; the second semiconductor structure 704 further includes a sixth conductive structure 742; and the sixth conductive structure 742 is located in the second dielectric structure 734; where the peripheral circuit 710 is coupled to the bit line 740 through the sixth conductive structure 742. For the bit line 740, refer to the related description of the bit line 222 shown in FIG. 2, and the bit line BL0 to BL2 shown in FIG. 5.

The sixth conductive structure 742 is configured to realize an electrical connection between the bit line 740 and the peripheral circuit 710. The bit line 740 may be coupled to the peripheral circuit 710 through a bonding contact across the bonding interface of the first semiconductor structure 702 and the second semiconductor structure 704 and a sixth conductive structure 742, sequentially.

In some examples, the first semiconductor structure 702 further includes a source line 756 coupled to the memory array 706, and the source line 756 is located between the memory array 706 and the bonding layer 708.

In some examples, the bonding layer 708 includes a bonding dielectric layer and bonding contacts 744 that extend through the bonding dielectric layer along a first direction. The bonding layer 708 includes a plurality of bonding contacts 744, which are isolated from each other by the bonding dielectric layer. The bonding contacts 744 may include a conductive material including, but not limited to, one or more of tungsten, cobalt, copper, aluminum, or polysilicon. As an example, the bonding contacts 744 of the bonding layer 708 include copper, the remaining region of the bonding layer 708 may be formed of dielectrics including, but not limited to, one or more of silicon oxide, silicon nitride, silicon oxynitride, or a low-k dielectric. The bonding contacts 744 and surrounding dielectrics in the bonding layer 708 may be used for hybrid bonding, and metal-to-metal bonding and dielectric-to-dielectric bonding may be obtained simultaneously.

In some examples, the first semiconductor structure 702 further includes a first bonding layer 746, the second semiconductor structure 704 further includes a second bonding layer 748, and the first bonding layer 746 is bonded to the second bonding layer 748, so that the first semiconductor structure 702 and the second semiconductor structure 704 are vertically connected. In the first semiconductor structure 702 and the second semiconductor structure 704, which are bonded, the first bonding layer 746 is located between the second semiconductor structure 704 and the memory array 706, and the second bonding layer 748 is located between the first bonding layer 746 and the peripheral circuit 710.

In some examples, the first semiconductor structure 702 further includes an interconnection dielectric layer 754 located between the bonding layer 708 and the first semiconductor layer 712. After the plurality of connection structures (for example, the first connection structure 718, the second connection structure 722, the third connection structure 726, and the fourth connection structure 730) are formed in the first semiconductor layer 712, the interconnection dielectric layer 754 may be formed on the back surface of the first semiconductor layer 712 and a plurality of interconnection structures may be formed in the interconnection dielectric layer 754, and the interconnection structures in the interconnection dielectric layer 754 are configured to realize the electrical connection between the connection structures in the first semiconductor layer 712 and the bonding contact 744.

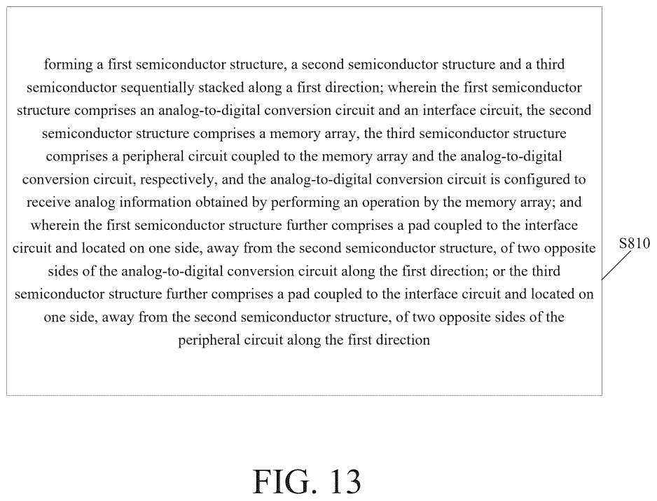

Based on the foregoing semiconductor device, an example of the present disclosure provides a method of manufacturing a semiconductor device. FIG. 13 is a schematic flowchart of a method of manufacturing a semiconductor device provided by an example of the present disclosure. Referring to FIG. 13, the method includes at least operation S810: forming a first semiconductor structure, a second semiconductor structure and a third semiconductor sequentially stacked along a first direction; where the first semiconductor structure includes an analog-to-digital conversion circuit and an interface circuit, the second semiconductor structure includes a memory array, the third semiconductor structure includes a peripheral circuit coupled to the memory array and the analog-to-digital conversion circuit, respectively; the analog-to-digital conversion circuit is configured to receive analog information obtained by performing an operation by the memory array; the first semiconductor structure further includes a pad coupled to the interface circuit and located on one side of two opposite sides of the analog-to-digital conversion circuit along the first direction away from the second semiconductor structure; or the third semiconductor structure further includes a pad coupled to the interface circuit and located on one side of two opposite sides of the peripheral circuit along the first direction away from the second semiconductor structure.

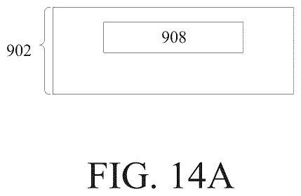

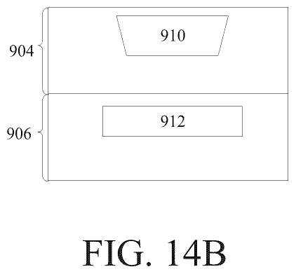

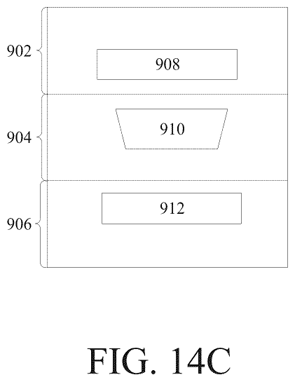

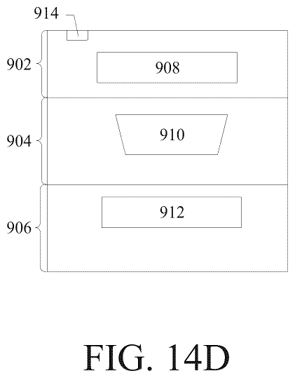

FIG. 14A to FIG. 14D are schematic diagrams of a manufacturing process of a semiconductor device provided by a first example of the present disclosure, and the method manufacturing of the semiconductor device provided by the example of the present disclosure will be described below with reference to FIG. 13 and FIG. 14A to FIG. 14D.

In some examples, referring to FIG. 14A to FIG. 14C, the operation S810 includes: forming a first semiconductor structure 902, a second semiconductor structure 904, and a third semiconductor structure 906, respectively; bonding a first side of the second semiconductor structure 904 to the first semiconductor structure 902, and bonding a second side of the second semiconductor structure 904 to the third semiconductor structure 906; where the first side of the second semiconductor structure 904 and the second side of the second semiconductor structure 904 are opposite to each other along the first direction.

As an example, a first semiconductor structure 902 as shown in FIG. 14A, a second semiconductor structure 904 and a third semiconductor structure 906 as shown in FIG. 14B may be formed, respectively; a second side of the second semiconductor structure 904 may be bonded to the third semiconductor structure 906, as shown in FIG. 14B; a first side of the second semiconductor structure 904 may be bonded to the first semiconductor structure 902, as shown in FIG. 14C. In this example, the second side of the second semiconductor structure 904 may be bonded to the third semiconductor structure 906 firstly, and then the first side of the second semiconductor structure 904 may be bonded to the first semiconductor structure 902. It should be noted that, in FIG. 14C, the front surface of the first semiconductor structure 902 faces the second semiconductor structure 904; thus, a carrier substrate may not be used.

In some examples, forming the first semiconductor structure 902 includes: forming the interface circuit and the analog-to-digital conversion circuit based on a first semiconductor layer; where both a portion of the analog-to-digital conversion circuit and a portion of the interface circuit are located in the first semiconductor layer.

As an example, the process of forming the first semiconductor structure 902 includes: providing a first semiconductor layer; forming a first active region 908 as shown in FIG. 14A in the first semiconductor layer; forming an analog-to-digital conversion circuit, an interface circuit, a data processing circuit, a controller, and the like on the front surface of the first semiconductor layer based on the first active region 908. Although only one first active region 908 is shown in FIG. 14A, in practical applications, a plurality of first active regions 908 may be formed in the first semiconductor layer, a plurality of CMOS transistors may be formed based on the plurality of first active regions 908, respectively, and the plurality of CMOS transistors may constitute the analog-to-digital conversion circuit and the interface circuit, respectively.

In some examples, forming the first semiconductor structure 902 further includes: forming a first conductive structure on one side of two opposite sides of the first semiconductor layer along the first direction close to the second semiconductor structure 904; where the first conductive structure is connected to the interface circuit.

As an example, the process of forming the first conductive structure includes: forming a first dielectric layer covering a front surface of the first semiconductor layer; etching the first dielectric layer to form a contact hole penetrating through the first dielectric layer; filling a conductive material into the contact hole to form a first contact structure; forming a first interconnection dielectric layer covering the first dielectric layer and the first contact structure; etching the first interconnection dielectric layer to form an interconnection trench exposing the first contact structure; and filling a conductive material into the interconnection trench to form a first interconnection structure. It may be understood that the first conductive structure includes a first contact structure and a first interconnection structure, and the first conductive structure is configured to electrically lead out the interface circuit.

In some examples, forming the first semiconductor structure 902 further includes: forming a second conductive structure on one side of two opposite sides of the first semiconductor layer along the first direction close to the second semiconductor structure 904, where the second conductive structure is connected to the analog-to-digital conversion circuit. Here, the second conductive structure is configured to electrically lead out the analog-to-digital conversion circuit. The second conductive structure may be formed simultaneously with the first conductive structure, and for the process of forming the second conductive structure, referring to the related description of the process of forming the first conductive structure.

In some examples, forming the first semiconductor structure 902 further includes: forming a pad 914 on one side of two opposite sides of the first semiconductor layer along the first direction away from the second semiconductor structure 904.

As an example, after bonding the first side of the second semiconductor structure 904 to the first semiconductor structure 902, the pad 914 as shown in FIG. 14D may be formed on the back surface of the first semiconductor layer.

In some examples, forming the first semiconductor structure 902 further includes: forming a first connection structure extending through the first semiconductor layer along the first direction; where the pad 914 is coupled to the interface circuit through the first connection structure.

As an example, after the first side of the second semiconductor structure 904 is bonded to the first semiconductor structure 902, the etching may be performed from the back surface of the first semiconductor layer to form a through-silicon via extending through the first semiconductor layer and exposing the first contact structure; a conductive material is filled into the through hole to form a first connection structure, and the interface circuit may be electrically led out through the first conductive structure and the first connection structure; a pad dielectric layer covering the back surface of the first semiconductor layer and the first connection structure is then formed; the pad dielectric layer is etched to form a pad trench exposing the first connection structure, and a conductive material is filled into the pad trench to form the pad 914 connected to the first connection structure. In practical applications, the first semiconductor layer may be thinned first, and then the pad may be formed on the back surface of the first semiconductor layer.

In some examples, forming the second semiconductor structure 904 includes: forming the memory array 910 based on the second semiconductor layer.

As an example, the process of forming the second semiconductor structure 904 includes: providing a second semiconductor layer; and forming the memory array 910 shown in FIG. 14B on the front surface of the second semiconductor layer.

In some examples, forming the second semiconductor structure 904 further includes: forming a third conductive structure, a fourth conductive structure and a fifth conductive structure on one side of two opposite sides of the second semiconductor layer along the first direction away from the first semiconductor structure 902; where the third conductive structure is configured to connect the analog-to-digital conversion circuit; and both the fourth conductive structure and the fifth conductive structure are configured to connect the controller, and the fourth conductive structure and the fifth conductive structure are configured to transmit different control signals, respectively.

As an example, the process of forming the third conductive structure, the fourth conductive structure and the fifth conductive structure includes: forming a second dielectric layer covering the step region of the memory array 910; etching the second dielectric layer to form a plurality of contact holes penetrating through the second dielectric layer; filling a conductive material into each contact hole to form a tenth contact structure, a fourth contact structure and a fifth contact structure, respectively; forming a second interconnection dielectric layer covering the second dielectric layer, the tenth contact structure, the fourth contact structure and the fifth contact structure; etching the second interconnection dielectric layer to form a plurality of interconnection trenches exposing the tenth contact structure, the fourth contact structure and the fifth contact structure, respectively; and filling the conductive material into each interconnection trench to form the third interconnection structure, the fourth interconnection structure and the fifth interconnection structure, respectively. It can be understood that the third conductive structure includes a tenth contact structure and a third interconnection structure, the fourth conductive structure includes a fourth contact structure and a fourth interconnection structure, and the fifth conductive structure includes a fifth contact structure and a fifth interconnection structure.

In some examples, forming the second semiconductor structure 904 further includes: forming a third connection structure, a fourth connection structure and a fifth connection structure extending through the second semiconductor layer along the first direction; where the third connection structure is connected to the third conductive structure, the fourth connection structure is connected to the fourth conductive structure, and the fifth connection structure is connected to the fifth conductive structure.

As an example, after the second side of the second semiconductor structure 904 is bonded to the third semiconductor structure 906, the etching may be performed from the back surface of the second semiconductor layer to form a plurality of through-silicon vias extending through the second semiconductor layer and exposing the tenth contact structure, the fourth contact structure and the fifth contact structure, respectively; and the conductive material is filled into each through-silicon via to form the third connection structure, the fourth connection structure, and the fifth connection structure.

In some examples, forming the third semiconductor structure 906 includes: forming a peripheral circuit based on the third semiconductor layer; where a portion of the peripheral circuit is located in the third semiconductor layer.

As an example, the process of forming the third semiconductor structure 906 includes: providing a third semiconductor layer; forming a second active region 912 as shown in FIG. 14B in the third semiconductor layer; and forming a peripheral circuit on the front surface of the third semiconductor layer based on the second active region 912. Although only one second active region 912 is shown in FIG. 14B, in practical applications, a plurality of second active regions 912 may be formed in the third semiconductor layer, and the peripheral circuit may be formed based on the plurality of second active regions 912.

In some examples, forming the third semiconductor structure 906 further includes: forming an eighth conductive structure on one side of two opposite sides of the third semiconductor layer along the first direction close to the second semiconductor structure 904; where the eighth conductive structure is connected to the peripheral circuit.

As an example, the process of forming the eighth conductive structure includes: forming a third dielectric layer covering the peripheral circuit; etching the third dielectric layer to form a contact hole penetrating through the third dielectric layer; filling a conductive material into the contact hole to form an eighth contact structure connected to the peripheral circuit; forming a third interconnection dielectric layer covering the third dielectric layer and the eighth contact structure; etching the third interconnection dielectric layer to form an interconnection trench exposing the eighth contact structure; and filling a conductive material into the interconnection trench to form an eighth interconnection structure. It can be understood that the eighth conductive structure includes an eighth contact structure and an eighth interconnection structure.

After bonding the second semiconductor structure 904 and the third semiconductor structure 906, the peripheral circuit may be coupled to the bit line through an eighth conductive structure and a bonding contact across the bonding interface of the second semiconductor structure 904 and the third semiconductor structure 906.

It may be understood that the semiconductor device shown in FIG. 8 may be formed by performing the process operations shown in FIG. 14A to FIG. 14D.

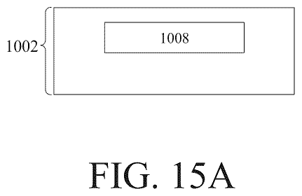

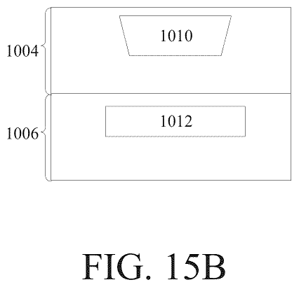

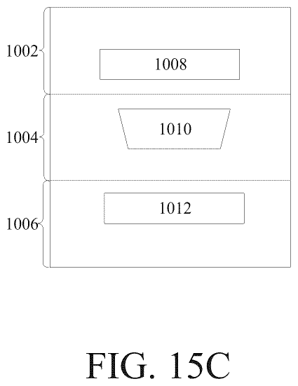

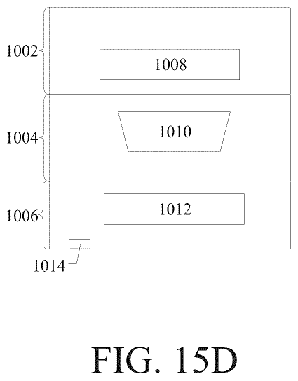

FIG. 15A to FIG. 15D are schematic diagrams of a manufacturing process of a semiconductor device provided by a second example of the present disclosure, and the method manufacturing of the semiconductor device provided by the examples of the present disclosure will be described below with reference to FIG. 13 and FIG. 15A to FIG. 15D.

In some examples, referring to FIG. 15A to FIG. 15C, the operation S810 includes: forming a first semiconductor structure 1002, a second semiconductor structure 1004, and a third semiconductor structure 1006, respectively; bonding a first side of the second semiconductor structure 1004 to the first semiconductor structure 1002, and bonding a second side of the second semiconductor structure 1004 to the third semiconductor structure 1006; where the first side of the second semiconductor structure 1004 and the second side of the second semiconductor structure 1004 are opposite to each other along the first direction.

As an example, a first semiconductor structure 1002 as shown in FIG. 15A, a second semiconductor structure 1004 and a third semiconductor structure 1006 as shown in FIG. 15B may be formed, respectively; a second side of the second semiconductor structure 1004 may be bonded to the third semiconductor structure 1006, as shown in FIG. 15B; a first side of the second semiconductor structure 1004 may be bonded to the first semiconductor structure 1002, as shown in FIG. 15C. In this example, the second side of the second semiconductor structure 1004 may be bonded to the third semiconductor structure 1006 firstly, and then the first side of the second semiconductor structure 1004 may be bonded to the first semiconductor structure 1002. It should be noted that, in FIG. 15C, the front surface of the first semiconductor structure 1002 faces the second semiconductor structure 1004, in this way, it is not necessary to use a carrier substrate.

In some examples, forming the first semiconductor structure 1002 includes: forming the interface circuit and the analog-to-digital conversion circuit based on a first semiconductor layer; where both a portion of the analog-to-digital conversion circuit and a portion of the interface circuit are located in the first semiconductor layer.

As an example, the process of forming the first semiconductor structure 1002 includes: providing a first semiconductor layer; forming a first active region 1008 as shown in FIG. 15A in the first semiconductor layer; forming an analog-to-digital conversion circuit, an interface circuit, a data processing circuit, a controller, and the like on the front surface of the first semiconductor layer based on the first active region 1008. Although only one first active region 1008 is shown in FIG. 15A, in practical applications, a plurality of first active regions 1008 may be formed in the first semiconductor layer, a plurality of CMOS transistors may be formed based on the plurality of first active regions 1008, respectively, and the plurality of CMOS transistors may constitute the analog-to-digital conversion circuit and the interface circuit, respectively.

In some examples, forming the first semiconductor structure 1002 further includes: forming a first conductive structure and a second conductive structure on one side of two opposite sides of the first semiconductor layer along the first direction close to the second semiconductor structure 1004; where the first conductive structure is connected to the interface circuit, and the second conductive structure is connected to the analog-to-digital conversion circuit. For the process of forming the first conductive structure and the second conductive structure, referring to the above related description.

In some examples, forming the second semiconductor structure 1004 includes: forming the memory array 1010 based on the second semiconductor layer.

As an example, the process of forming the second semiconductor structure 1004 includes: providing a second semiconductor layer; and forming the memory array 1010 shown in FIG. 15B on the front surface of the second semiconductor layer.

In some examples, forming the second semiconductor structure 1004 further includes: forming a third conductive structure, a fourth conductive structure, a fifth conductive structure and a sixth conductive structure on one side of two opposite sides of the second semiconductor layer along the first direction away from the first semiconductor structure 1002; where the third conductive structure is configured to connect the analog-to-digital conversion circuit; and both the fourth conductive structure and the fifth conductive structure are configured to connect the controller, and the fourth conductive structure and the fifth conductive structure are configured to transmit different control signals, respectively; and the sixth conductive structure is configured to connect the first conductive structure. Here, the sixth conductive structure may be formed simultaneously with the third conductive structure, the fourth conductive structure, and the fifth conductive structure, and for the process of forming the third conductive structure, the fourth conductive structure, and the fifth conductive structure, referring to the above related description.

In some examples, forming the second semiconductor structure 1004 further includes: forming a third connection structure, a fourth connection structure, a fifth connection structure and a sixth connection structure extending through the second semiconductor layer along the first direction; where the third connection structure is connected to the third conductive structure, the fourth connection structure is connected to the fourth conductive structure, the fifth connection structure is connected to the fifth conductive structure, and the sixth connection structure is connected to the sixth conductive structure. Here, the sixth connection structure may be formed simultaneously with the third connection structure, the fourth connection structure, and the fifth connection structure, and for the process of forming the third connection structure, the fourth connection structure, and the fifth connection structure, refer to the above related description.

In some examples, forming the third semiconductor structure 1006 includes: forming a peripheral circuit based on the third semiconductor layer; where a portion of the peripheral circuit is located in the third semiconductor layer.

As an example, the process of forming the third semiconductor structure 1006 includes: providing a third semiconductor layer; forming a second active region 1012 as shown in FIG. 15B in the third semiconductor layer; and forming a peripheral circuit on the front surface of the third semiconductor layer based on the second active region 1012. Although only one second active region 1012 is shown in FIG. 15B, in practical applications, a plurality of second active regions 1012 may be formed in the third semiconductor layer, and the peripheral circuit may be formed based on the plurality of second active regions 1012.

In some examples, forming the third semiconductor structure 1006 further includes: forming a seventh conductive structure and an eighth conductive structure on one side of two opposite sides of the third semiconductor layer along the first direction close to the second semiconductor structure 1004; where the seventh conductive structure is configured to connect the sixth conductive structure, and the eighth conductive structure is connected to the peripheral circuit. Here, the seventh conductive structure may be formed simultaneously with the eighth conductive structure, and for the process of forming the eighth conductive structure, refer to the above related description.

After bonding the second semiconductor structure 1004 and the third semiconductor structure 1006, the seventh conductive structure may be coupled to the sixth conductive structure by a bonding contact across the bonding interface of the second semiconductor structure 1004 and the third semiconductor structure 1006.

In some examples, forming the third semiconductor structure 1006 further includes: forming a pad 1014 on one side of two opposite sides of the third semiconductor layer along the first direction away from the second semiconductor structure 1004.

As an example, after bonding the second side of the second semiconductor structure 1004 to the third semiconductor structure 1006, the pad 1014 as shown in FIG. 15D may be formed on the back surface of the third semiconductor layer.

In some examples, forming the third semiconductor structure 1006 further includes: forming a seventh connection structure extending through the third semiconductor layer along the first direction; where the seventh connection structure is connected to the seventh conductive structure and the pad 1014, respectively.

As an example, after the second side of the second semiconductor structure 1004 is bonded to the third semiconductor structure 1006, the etching may be performed from the back surface of the third semiconductor layer to form a through-silicon via extending through the third semiconductor layer and exposing the seventh contact structure; a conductive material is filled into the through hole to form a seventh connection structure; a pad dielectric layer covering the back surface of the third semiconductor layer and the seventh connection structure is then formed; the pad dielectric layer is etched to form a pad trench exposing the seventh connection structure, and a conductive material is filled into the pad trench to form a pad 1014 connected to the seventh connection structure. In practical applications, the third semiconductor layer may be thinned first, and then the pad may be formed on the back surface of the third semiconductor layer.

It may be understood that the semiconductor device shown in FIG. 10 may be formed by performing the process operations shown in FIG. 15A to FIG. 15D.

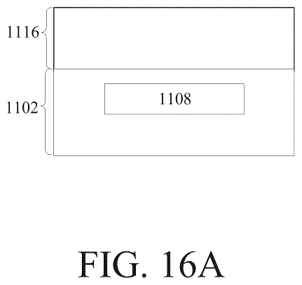

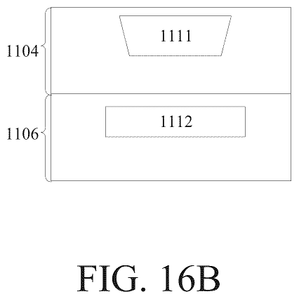

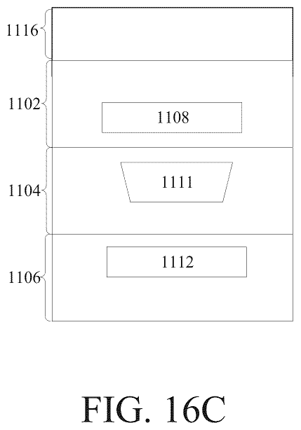

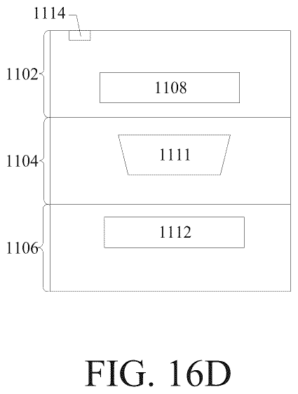

FIG. 16A to FIG. 16D are schematic diagrams of a method of manufacturing a semiconductor device provided by a third example of the present disclosure, and the method manufacturing of the semiconductor device provided by the example of the present disclosure will be described below with reference to FIG. 13 and FIG. 16A to FIG. 16D.

In some examples, the operation S810 includes: forming a first semiconductor structure 1102, a second semiconductor structure 1104, and a third semiconductor structure 1106, respectively; bonding a first side of the second semiconductor structure 1104 to the first semiconductor structure 1102, and bonding a second side of the second semiconductor structure 1104 to the third semiconductor structure 1106; where the first side of the second semiconductor structure 1104 and the second side of the second semiconductor structure 1104 are opposite to each other along the first direction.

As an example, a first semiconductor structure 1102 as shown in FIG. 16A, a second semiconductor structure 1104 and a third semiconductor structure 1106 as shown in FIG. 16B may be formed, respectively; a second side of the second semiconductor structure 1104 may be bonded to the third semiconductor structure 1106, as shown in FIG. 16B; a first side of the second semiconductor structure 1104 may be bonded to the first semiconductor structure 1102, as shown in FIG. 16C. In this example, the second side of the second semiconductor structure 1104 may be bonded to the third semiconductor structure 1106 firstly, and then the first side of the second semiconductor structure 1104 may be bonded to the first semiconductor structure 1102.

It should be noted that, in FIG. 16C, the back surface of the first semiconductor structure 1102 faces the second semiconductor structure 1104, and in order to protect the structure formed on the front surface of the first semiconductor structure 1102, before the first side of the second semiconductor structure 1104 is bonded to the first semiconductor structure 1102, the front surface of the first semiconductor structure 1102 needs to be bonded to the carrier substrate 1116, as shown in FIG. 16A and FIG. 16C. After the first side of the second semiconductor structure 1104 is bonded to the first semiconductor structure 1102, the carrier substrate 1116 may be removed, as shown in FIG. 16D.

In some examples, forming the first semiconductor structure 1102 includes: forming the interface circuit and the analog-to-digital conversion circuit based on a first semiconductor layer; where both a portion of the analog-to-digital conversion circuit and a portion of the interface circuit are located in the first semiconductor layer.

As an example, the process of forming the first semiconductor structure 1102 includes: providing a first semiconductor layer; forming a first active region 1108 as shown in FIG. 16A in the first semiconductor layer; forming an analog-to-digital conversion circuit, an interface circuit, a data processing circuit, a controller, and the like on the front surface of the first semiconductor layer based on the first active region 1108. Although only one first active region 1108 is shown in FIG. 16A, in practical applications, a plurality of first active regions 1108 may be formed in the first semiconductor layer, a plurality of CMOS transistors may be formed based on the plurality of first active regions 1108, respectively, and the plurality of CMOS transistors may constitute the analog-to-digital conversion circuit, the interface circuit and the like, respectively.

In some examples, forming the first semiconductor structure 1102 further includes: forming a first conductive structure on one side of two opposite sides of the first semiconductor layer along the first direction away from the second semiconductor structure 1104; where the first conductive structure is connected to the interface circuit.

As an example, the process of forming the first conductive structure includes: forming a first dielectric layer covering a front surface of the first semiconductor layer; etching the first dielectric layer to form a contact hole penetrating through the first dielectric layer; filling a conductive material into the contact hole to form a first contact structure; forming a first interconnection dielectric layer covering the first dielectric layer and the first contact structure; etching the first interconnection dielectric layer to form an interconnection trench exposing the first contact structure; and filling a conductive material into the interconnection trench to form a first interconnection structure. It may be understood that the first conductive structure includes a first contact structure and a first interconnection structure, and the first conductive structure is configured to electrically lead out the interface circuit.

In some examples, forming the first semiconductor structure 1102 further includes: forming a pad 1114 on one side of two opposite sides of the first semiconductor layer along the first direction away from the second semiconductor structure 1104.

As an example, after bonding the first side of the second semiconductor structure 1104 to the first semiconductor structure 1102, the pad 1114 as shown in FIG. 16D may be formed on the front surface of the first semiconductor layer.

In some examples, forming the pad 1114 on one side of two opposite sides of the first semiconductor layer along the first direction away from the second semiconductor structure 1104 includes: forming the pad 1114 on one side of two opposite sides of the first conductive structure along the first direction away from the first semiconductor layer; where the pad 1114 is connected to the first conductive structure.

As an example, after the first conductive structure is formed, a pad dielectric layer covering the first interconnection dielectric layer and the first interconnection structure may be formed; the pad dielectric layer is etched to form a pad trench exposing the first interconnection structure, and a conductive material is filled into the pad trench to form the pad 1114 connected to the first interconnection structure.

In some examples, forming the second semiconductor structure 1104 includes: forming the memory array 1110 based on the second semiconductor layer.

As an example, the process of forming the second semiconductor structure 1104 includes: providing a second semiconductor layer; and forming the memory array 1110 shown in FIG. 16B on the front surface of the second semiconductor layer.

In some examples, forming the third semiconductor structure 1106 includes: forming a peripheral circuit based on the third semiconductor layer; where a portion of the peripheral circuit is located in the third semiconductor layer.

As an example, the process of forming the third semiconductor structure 1106 includes: providing a third semiconductor layer; forming a second active region 1112 as shown in FIG. 16B in the third semiconductor layer; and forming a peripheral circuit on the front surface of the third semiconductor layer based on the second active region 1112. Although only one second active region 1112 is shown in FIG. 16B, in practical applications, a plurality of second active regions 1112 may be formed in the third semiconductor layer, and the peripheral circuit may be formed based on the plurality of second active regions 1112.

It may be understood that the semiconductor device shown in FIG. 11 may be formed by performing the process operations shown in FIG. 16A to FIG. 16D.

Based on the foregoing semiconductor device, an example of the present disclosure further provides a package structure.

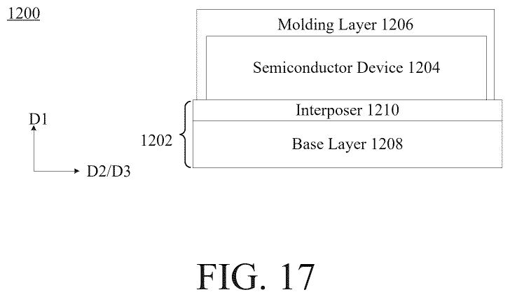

FIG. 17 is a schematic diagram of a package structure provided by an example of the present disclosure. Referring to FIG. 17, the package structure 1200 includes a package substrate 1202, a semiconductor device 1204, and a molding layer 1206; the semiconductor device 1204 is disposed on the package substrate 1202; and the molding layer 1206 encapsulates the semiconductor device 1204.

In some examples, referring to FIG. 17, the package substrate 1202 includes a base layer 1208 and an interposer 1210 formed on the base layer, a connection circuit is formed in the interposer 1210, and the semiconductor device 1204 is disposed on one side of the interposer 1210 away from the base layer 1208.

Here, the semiconductor device 1204 may be the semiconductor device according to any one of the above examples. Since the package structure in this example adopts all the technical solutions of all the above examples, it at least has all the beneficial effects brought by the technical solutions of the foregoing examples, and details are not described herein again.

Based on the foregoing semiconductor device, an example of the present disclosure further provides an electronic device.

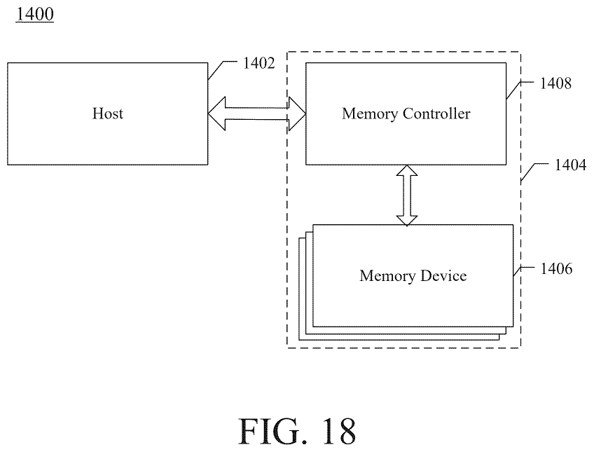

FIG. 18 is a schematic diagram of an example electronic device having a semiconductor device provided by an example of the present disclosure. Referring to FIG. 18, the electronic device 1400 includes a host 1402 and a semiconductor device 1404; and the host 1402 is coupled to the semiconductor device 1404.

In an example of the present disclosure, the electronic device 1400 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having storage therein.

As shown in FIG. 18, the semiconductor device 1404 may include one or more memory devices 1406 and a memory controller 1408. The host 1402 may include a processor of an electronic device (e.g., a central processing unit (CPU), a system on a chip (SoC), an application processor (AP), etc.). The host 1402 may be configured to send or receive data to or from the semiconductor device 1404. The memory device 1406 includes a memory array and a peripheral circuit coupled to the memory array. The memory controller 1408 herein may be the controller in the foregoing example of the semiconductor device.

In some implementations, the memory controller 1408 is coupled to the memory device 1406 and the host 1402 and is configured to control the memory device 1406. The memory controller 1408 may manage data stored in the memory device 1406 and communicate with the host 1402. In some implementations, the memory controller 1408 is designed to operate in a low duty cycle environment, such as a secure digital (SD) card, a compact flash card (CFC), an universal serial bus (USB) flash drive, or other medium for use in electronic devices such as a personal computer, a digital camera, a mobile phone and the like. In some other implementations, the memory controller 1408 is designed to operate in a high duty cycle environment, such as a solid state disk or an embedded multi-media card (eMMC).

In some examples, the memory controller 1408 and the one or more memory devices 1406 may be integrated into various types of memory devices, that is, the semiconductor device 1404 may be implemented and packaged into different types of end electronics.

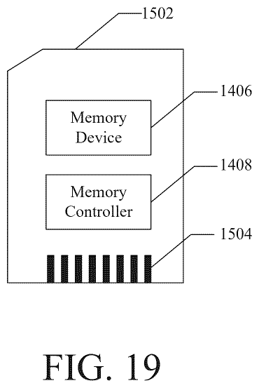

In one example as shown in FIG. 19, the memory controller 1408 and the single memory device 1406 may be integrated into the memory card 1502. The memory card 1502 may be one of a compact flash memory card, a smart media card (SMC), a memory stick (MS), a multimedia card (MMC) (for example, an reduced size (RS)-MMC, an MMCmicro, an embedded (eMMC), and the like), a secure digital (SD) card (for example, a Mini SD card, a Micro SD card, an SD high-capacity (HC) (SDHC) card, and the like), and a universal flash memory card. The memory card 1502 may also include a memory card connector 1504 that couples the memory card 1502 with a host-side device (e.g., host 1402 in FIG. 18).

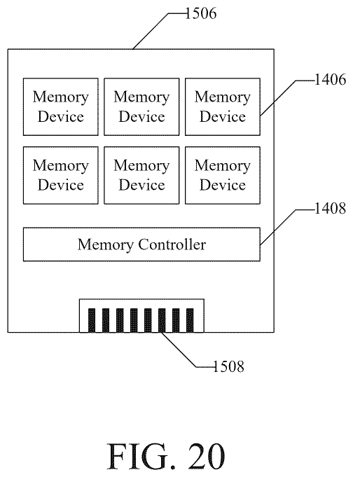

In another example as shown in FIG. 20, the memory controller 1408 and the plurality of memory devices 1406 may be integrated into SSD 1506. SSD 1506 may also include an SSD connector 1508 that couples SSD 1506 with a host-side device (e.g., host 1402 in FIG. 18). In some implementations, at least one of the memory capacity or the operating speed of SSD 1506 is greater than at least one of the memory capacity or the operating speed of the memory card 1502.

The features disclosed in the several device examples according to the present disclosure may be arbitrarily combined without conflict, to obtain a new device example.

The methods disclosed in the several method examples according to the present disclosure may be arbitrarily combined without conflict, to obtain a new method example.

It should be understood that “one example” or “an example” mentioned throughout the specification means that specific features, structures, or characteristics related to the examples are included in at least one example of the present disclosure. Thus, “in one example” or “in an example” appearing throughout the specification need not necessarily refer to the same example. Further, these particular features, structures, or characteristics may be incorporated in one or more examples in any suitable manner. It should be understood that, in various examples of the present disclosure, the sequence numbers of the above processes do not mean an order of execution sequences, and an execution sequence of each process should be determined by using a function and an intrinsic logic thereof, and should not constitute any limitation on an implementation process of the examples of the present disclosure. The above sequence numbers of the examples of the present disclosure are merely for description, and do not represent the advantages of the examples.

It should be noted that, in this specification, the terms “including,” “including,” or any other variant thereof are intended to cover a non-exclusive inclusion, such that a process, method, article, or apparatus that includes a series of elements includes not only those elements but also other elements not explicitly listed, or elements inherent to such processes, methods, articles, or apparatuses. Without further restriction, the elements defined by the statement “comprise one. . . ” do not preclude the presence of additional identical elements in the process, method, article, or apparatus that includes the element.

The above descriptions are only implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a first semiconductor structure, a second semiconductor structure and a third semiconductor structure sequentially stacked along a first direction;
wherein the first semiconductor structure comprises an analog-to-digital conversion circuit and an interface circuit, the second semiconductor structure comprises a memory array, the third semiconductor structure comprises a peripheral circuit coupled to the memory array and the analog-to-digital conversion circuit, respectively, and the analog-to-digital conversion circuit is configured to receive analog information obtained by performing an operation by the memory array; and
wherein the first semiconductor structure further comprises a pad coupled to the interface circuit and located on one side, away from the second semiconductor structure, of two opposite sides of the analog-to-digital conversion circuit along the first direction; or the third semiconductor structure further comprises a pad coupled to the interface circuit and located on one side, away from the second semiconductor structure, of two opposite sides of the peripheral circuit along the first direction.

2. The semiconductor device of claim 1, wherein the first semiconductor structure further comprises a first semiconductor layer located between the pad and the second semiconductor structure, and wherein both a portion of the analog-to-digital conversion circuit and a portion of the interface circuit are located in the first semiconductor layer.

3. The semiconductor device of claim 2, wherein the first semiconductor structure further comprises a first dielectric structure, a first conductive structure, and a second conductive structure;
wherein the first dielectric structure is located between the first semiconductor layer and the second semiconductor structure, and both the first conductive structure and the second conductive structure are located in the first dielectric structure; and
wherein the pad is coupled to the interface circuit through the first conductive structure, and the peripheral circuit is coupled to the analog-to-digital conversion circuit through the second conductive structure.

4. The semiconductor device of claim 3, wherein the first semiconductor structure further comprises a first connection structure extending through the first semiconductor layer along the first direction, and wherein two opposite ends of the first connection structure along the first direction are connected to the pad and the first conductive structure, respectively.

5. The semiconductor device of claim 4, wherein the first dielectric structure comprises a first dielectric layer and a first interconnection dielectric layer, the first dielectric layer is located between the first semiconductor layer and the first interconnection dielectric layer, and the first interconnection dielectric layer is located between the first dielectric layer and the second semiconductor structure;
wherein the first conductive structure comprises a first contact structure and a first interconnection structure, the first contact structure extends through the first dielectric layer along the first direction, and the first interconnection structure is located in the first interconnection dielectric layer, and wherein two opposite ends of the first contact structure along the first direction are connected to the first connection structure and the first interconnection structure, respectively; and
wherein the second conductive structure comprises a second contact structure and a second interconnection structure, the second contact structure extends through the first dielectric layer along the first direction, and the second interconnection structure is located in the first interconnection dielectric layer, and wherein two opposite ends of the second contact structure along the first direction are connected to the analog-to-digital conversion circuit and the second interconnection structure, respectively.

6. The semiconductor device of claim 2, wherein the first semiconductor structure further comprises a first dielectric structure, a first conductive structure, and a second conductive structure;
wherein the first dielectric structure is located between the pad and the first semiconductor layer, and both the first conductive structure and the second conductive structure are located in the first dielectric structure; and
wherein the pad is coupled to the interface circuit through the first conductive structure, and the peripheral circuit is coupled to the analog-to-digital conversion circuit through the second conductive structure.

7. The semiconductor device of claim 6, wherein the first semiconductor structure further comprises a first connection structure extending through the first semiconductor layer along the first direction, and wherein the peripheral circuit is coupled to the second conductive structure through the first connection structure.

8. The semiconductor device of claim 7, wherein the first dielectric structure comprises a first dielectric layer and a first interconnection dielectric layer, the first dielectric layer is located between the first semiconductor layer and the first interconnection dielectric layer, and the first interconnection dielectric layer is located between the first dielectric layer and the pad;
wherein the first conductive structure comprises a first contact structure and a first interconnection structure, the first contact structure extends through the first dielectric layer along the first direction, and the first interconnection structure is located in the first interconnection dielectric layer, and wherein the pad is connected to the first interconnection structure, and two opposite ends of the first contact structure along the first direction are connected to the first interconnection structure and the interface circuit, respectively; and
wherein the second conductive structure comprises a second contact structure, a third contact structure, and a conductive line, both the second contact structure and the third contact structure extend through the first dielectric layer along the first direction, and the conductive line is located in the first interconnection dielectric layer, and wherein two opposite ends of the second contact structure along the first direction are connected to the analog-to-digital conversion circuit and the conductive line, respectively, and two opposite ends of the third contact structure along the first direction are connected to the first connection structure and the conductive line, respectively.

9. The semiconductor device of claim 7, wherein the first semiconductor structure further comprises a second connection structure and a controller, the second connection structure extends through the first semiconductor layer along the first direction, and a portion of the controller is located in the first semiconductor layer; and
wherein the peripheral circuit is coupled to the controller through the second connection structure.

10. The semiconductor device of claim 1, wherein the second semiconductor structure further comprises a second semiconductor layer, a second dielectric structure, a third conductive structure and a third connection structure;
wherein the second semiconductor layer is located between the first semiconductor structure and the second dielectric structure, the second dielectric structure covers a step region of the memory array, the third conductive structure is located in the second dielectric structure, and the third connection structure extends through the second semiconductor layer along the first direction; and
wherein the peripheral circuit is coupled to the analog-to-digital conversion circuit through the third conductive structure and the third connection structure.

11. The semiconductor device of claim 10, wherein the first semiconductor structure further comprises a first semiconductor layer and a controller, and a portion of the controller is located in the first semiconductor layer;
wherein the second semiconductor structure further comprises a fourth conductive structure and a fourth connection structure, the fourth conductive structure is located in the second dielectric structure, and the fourth connection structure extends through the second semiconductor layer along the first direction; and
wherein the controller is coupled to the peripheral circuit through the fourth connection structure and the fourth conductive structure.

12. The semiconductor device of claim 11, wherein the second semiconductor structure further comprises a fifth conductive structure and a fifth connection structure, the fifth conductive structure is located in the second dielectric structure, and the fifth connection structure extends through the second semiconductor layer along the first direction; and
wherein the controller is further coupled to the peripheral circuit through the fifth connection structure and the fifth conductive structure, and the fifth connection structure and the fourth connection structure are configured to transmit different control signals, respectively.

13. The semiconductor device of claim 10, wherein the second semiconductor structure further comprises a sixth conductive structure and a sixth connection structure, the sixth conductive structure is located in the second dielectric structure, and the sixth connection structure extends through the second semiconductor layer along the first direction;
wherein the third semiconductor structure further comprises a third semiconductor layer, a third dielectric structure, a seventh conductive structure and a seventh connection structure, the third semiconductor layer is located between the pad and the third dielectric structure, and a portion of the peripheral circuit is located in the third semiconductor layer, the third dielectric structure is located between the third semiconductor layer and the second semiconductor structure, and the seventh conductive structure is located in the third dielectric structure, the seventh connection structure extends through the third semiconductor layer along the first direction; and
wherein the pad is coupled to the interface circuit through the seventh connection structure, the seventh conductive structure, the sixth conductive structure, and the sixth connection structure.

14. The semiconductor device of claim 13, wherein the second semiconductor structure further comprises a bit line coupled to the memory array, and the bit line is located between the memory array and the third semiconductor structure; and
wherein the third semiconductor structure further comprises an eighth conductive structure located in the third dielectric structure, and wherein the peripheral circuit is coupled to the bit line through the eighth conductive structure.

15. The semiconductor device of claim 1, wherein the first semiconductor structure further comprises a first dielectric structure and a ninth conductive structure, the first dielectric structure is located between the pad and the second semiconductor structure, and the ninth conductive structure is located in the first dielectric structure;
wherein the second semiconductor structure further comprises a source line coupled to the memory array, and the source line is located between the memory array and the first semiconductor structure; and
wherein the ninth conductive structure is coupled to the source line and the analog-to-digital conversion circuit, respectively, and an analog operation result is transmitted to the analog-to-digital conversion circuit through the source line and the ninth conductive structure.

16. The semiconductor device of claim 1, wherein a first side of the second semiconductor structure is bonded to the first semiconductor structure, and a second side of the second semiconductor structure is bonded to the third semiconductor structure; and wherein the first side of the second semiconductor structure is opposite to the second side of the second semiconductor structure along the first direction.

17. A semiconductor device, comprising:
a first semiconductor structure and a second semiconductor structure sequentially stacked along a first direction;
wherein the first semiconductor structure comprises a memory array and a bonding layer, the bonding layer is located on one side, away from the second semiconductor structure, of two opposite sides of the memory array along the first direction; and
wherein the second semiconductor structure comprises a peripheral circuit and a pad, the peripheral circuit is coupled to the memory array, and wherein the pad is located on one side, away from the first semiconductor structure, of two opposite sides of the peripheral circuit along the first direction, and the pad is configured to output an operation result obtained by performing an operation by the memory array.

18. The semiconductor device of claim 17, wherein the first semiconductor structure further comprises a first semiconductor layer, a first dielectric structure, a first conductive structure, and a first connection structure,
wherein the first semiconductor layer is located between the first bonding layer and the first dielectric structure, the first dielectric structure covers a step region of the memory array, the first conductive structure is located in the first dielectric structure, and the first connection structure extends through the first semiconductor layer along the first direction; and
wherein the peripheral circuit is coupled to the first connection structure through the first conductive structure, and the first connection structure is configured to transmit analog information obtained by performing an operation by the memory array.

19. The semiconductor device of claim 18, wherein the first semiconductor structure further comprises a second conductive structure and a second connection structure, the second conductive structure is located in the first dielectric structure, and the second connection structure extends through the first semiconductor layer along the first direction; and
wherein the peripheral circuit is coupled to the second connection structure through the second conductive structure, and the second connection structure is configured to transmit a first control signal.

20. A method of manufacturing a semiconductor device, comprising:
forming a first semiconductor structure, a second semiconductor structure and a third semiconductor structure sequentially stacked along a first direction;
wherein the first semiconductor structure comprises an analog-to-digital conversion circuit and an interface circuit, the second semiconductor structure comprises a memory array, the third semiconductor structure comprises a peripheral circuit coupled to the memory array and the analog-to-digital conversion circuit, respectively, and the analog-to-digital conversion circuit is configured to receive analog information obtained by performing an operation by the memory array; and
wherein the first semiconductor structure further comprises a pad coupled to the interface circuit and located on one side, away from the second semiconductor structure, of two opposite sides of the analog-to-digital conversion circuit along the first direction; or the third semiconductor structure further comprises a pad coupled to the interface circuit and located on one side, away from the second semiconductor structure, of two opposite sides of the peripheral circuit along the first direction.
